(19) United States
(12) Patent Application Publication
(10) Pub. No.: US 2012/0013590 A1
(43) Pub. Date: Jan. 19, 2012

(54) Organic electroluminescent display device, method of manufacturing organic electroluminescent display device, and electronic apparatus

(75) Inventors: Tetsuo Minami, Tokyo (JP); Katsuhide Uchino, Kanagawa (JP)

(73) Assignee: Sony Corporation, Tokyo (JP)

(21) Appl. No.: 13/067,273

(22) Filed: May 20, 2011

(30) Foreign Application Priority Data
Jul. 15, 2010 (JP) 2010-160407

(51) Int. Cl. G09G 3/30; G06F 3/038; H01L 33/62

(52) U.S. Cl. 345/211; 438/34; 257/E33.062; 345/80

(57) ABSTRACT

Disclosed is an organic electroluminescent (EL) display device including a pixel array section in which pixels having organic EL elements are arranged; and a drive circuit section provided in a circumferential portion of the pixel array section on the same substrate as that of the pixel array section, the drive circuit section having a circuit configuration including a capacitive element, wherein the capacitive element uses, as a dielectric member, an organic layer formed in the circumferential portion of the pixel array section through the same process as that of the organic layer of the organic EL element.

### BACKGROUND

The present disclosure relates to an organic EL display device, a method of manufacturing an organic EL display device, and an electronic apparatus, and particularly to, an organic EL display device obtained by mounting a drive circuit unit having a circuit configuration containing a capacitive element onto the same substrate as that of a pixel array section, a method of manufacturing the same, and an electronic apparatus.

Recently, in the field of display devices that perform image display, a flat type (flat panel type) display device has rapidly become widespread, in which pixels (pixel circuits) are arranged in a matrix shape. As one of the flat type display devices, there is a display device that uses, as a light-emitting element of the pixel, a so-called current-driven type electro-optic element in which luminance of emitted light changes depending on the electric current value flowing through the device. As the current-driven type electro-optic element, there is an organic EL element which uses an organic electroluminescent (EL) material, where light is emitted when an electric field is applied to an organic thin-film.

The organic EL display device which uses the organic EL element as a luminescent element of the pixel has the following characteristics. Specifically, the organic EL element has low power consumption as it can be driven by a voltage equal to or lower than 10 V. Since the organic EL element is a self-light-emitting element, image visibility is excellent in comparison with a liquid crystal display device. Furthermore, since an illumination member such as a backlight unit is not necessary, a light weight and a thin thickness are facilitated. Moreover, since the organic EL element has a very rapid response time such as several microseconds, no afterimage is generated when a moving picture is displayed.

Similar to the liquid crystal display device, the organic EL display device can be classified into a passive matrix type and an active matrix type considering the driving method. Here, the passive matrix type display device has a simple structure, but a light-emitting period of the organic EL element is reduced as the scanning line (that is, the number of pixels) increases. Therefore, the passive matrix type display device has some problems such as difficulty in realizing a large-size and high-precision display device.

For this reason, recently, the active matrix type display devices continue to be developed, in which the electric current flowing through the electro-optical element is controlled by an active element, for example, an insulated-gate field-effect transistor, provided in the same pixel together with the electro-optic element. Typically, a thin-film transistor (TFT) is used as the insulated gate field effect transistor. Using the active matrix type display device, it is easy to realize a large-size and high-precision organic EL display device as the electro-optic element continues to emit light across a single display frame period.

In general, it is understood that a characteristic of an electric current I versus a voltage V of the organic EL element is degraded (so called, time degradation) as time elapses. Particularly, when an N-channel TFT is used as a transistor for driving the organic EL element (hereinafter, referred to as a “drive transistor”), the gate-source voltage V_{gs} of the drive transistor changes as the I-V characteristic of the organic EL element is degraded due to time passage. Therefore, luminance of emitted light of the organic EL element changes.

In addition, a threshold voltage Vₜₕ or mobility μ of the drive transistor may temporally change, or may be different in each pixel because of deviations of a manufacturing process. When the threshold voltage Vₜₕ or mobility μ is different in each pixel, the electric current value flowing through the drive transistor is deviated in each pixel. As a result, even when a uniform voltage is applied to between the gates of the drive transistors of pixels, luminance of the light emitted from the organic EL element is deviated between pixels. Therefore, uniformity of display is degraded.

In this regard, the pixel circuit is provided with various correction (compensation) functionalities in order to constantly maintain the luminance of the light emitted from the organic EL element without influence from time degradation of the I-V characteristic of the organic EL element or temporal change of the transistor characteristic of the drive transistor (for example, refer to Japanese Unexamined Patent Application Publication No. 2008-083272).

### SUMMARY

In the active matrix type organic EL display device described above, a drive circuit section around the pixel array section, for example, a scanning circuit for sequentially selecting each pixel basically includes a shift register circuit as a main component. In addition, the scanning circuit has a buffer circuit in each transfer stage of the shift register circuit to match with each row of the pixel array section. In addition, the shift register circuit or the buffer circuit typically includes an inverter circuit.

However, for the purpose of lowering cost, the drive circuit section is often configured using a single-channel transistor. Here, the single-channel transistor refers to only an N-channel transistor or only a P-channel transistor. In addition, when the inverter circuit included in the shift register circuit or the buffer circuit is configured using the single-channel transistor, a circuit configuration obtained by combining a transistor with a capacitive element is employed in order to guarantee reliable operations of the inverter circuit (as will be described below in detail).

In this manner, if the drive circuit section is configured using an inverter circuit having a single-channel transistor combined with a capacitive element, the number of capacitive elements used in the entirety of the drive circuit section significantly increases. In addition, when the display panel is configured by mounting the drive circuit section having such a configuration onto the same substrate as that of a pixel array section, a layout area occupied by the capacitive element within the drive circuit section increases. Therefore, there may a problem in that a circumferential portion (a so called, bezel) of the pixel array section may be enlarged.

It is desirable to provide an organic EL display device capable of narrowing a bezel of a display panel when a drive circuit section having an inverter circuit of a circuit configuration including a capacitive element is mounted onto the display panel, a method of manufacturing the same, and an electronic apparatus having the same.

According to an embodiment of the present disclosure, there is provided an organic electroluminescent (EL) display device including a pixel array section in which pixels having organic EL elements are arranged; and a drive circuit section provided in a circumferential portion of the pixel array section on the same substrate as that of the pixel array section, the drive circuit section having a circuit configuration including a capacitive element, wherein the capacitive element uses, as a dielectric member, an organic layer formed in the circumferential portion of the pixel array section through the same process as that of the organic layer of the organic EL element.

In the organic EL display device having the aforementioned configuration, even when an organic layer used as a dielectric member of the capacitive element is formed in a circumferential portion of the pixel array section, the organic layer is formed through the same process as that of the organic layer of the organic EL element. Therefore, the number of manufacturing processes does not increase. In addition, since the organic layer formed in the circumferential portion of the pixel array section is used as a dielectric member of the capacitive element, the area under the organic layer can be freely used to form other circuit parts. As a result, since it is not necessary to separately prepare the area for forming other circuit parts, it is possible to reduce the layout area occupied by the drive circuit section, and further, the area of the circumferential portion of the pixel array section (that is, a bezel of the display panel) by that extent.

According to the embodiment of the present disclosure, it is possible to narrow a bezel of a display panel when a drive circuit section having a circuit configuration including a capacitive element is mounted onto the display panel.

### BRIEF DESCRIPTION OF THE DRAWINGS

FIG. 1 is a system configuration diagram illustrating a schematic configuration of an active matrix type organic EL display device according to an embodiment of the present disclosure.

FIG. 2 is a circuit diagram illustrating an example of a circuit configuration of a pixel (pixel circuit) in detail.

FIG. 3 is a timing waveform chart for describing basic circuit operation of an organic EL display device according to an embodiment of the present disclosure.

FIGS. 4A to 4D are (first) diagrams for describing basic circuit operation of an organic EL display device according to an embodiment of the present disclosure.

FIGS. 5A to 5D are (second) diagrams for describing basic circuit operation of an organic EL display device according to an embodiment of the present disclosure.

FIGS. 6A and 6B are characteristic plots for describing problems caused by deviations of a threshold voltage Vₜₕ of the drive transistor and for describing problems caused by deviations of mobility μ of a drive transistor, respectively.

FIG. 7 is a block diagram illustrating an exemplary configuration of a write scanning circuit.

FIGS. 8A to 8C are diagrams for describing operation of a shift register circuit as a main part of the write scanning circuit.

FIG. 9 is a timing waveform chart for describing operation of the shift register circuit.

FIGS. 10A and 10B are diagrams for describing an inverter circuit obtained by combining a single-channel transistor and a capacitive element, in which FIG. 10A illustrates an exemplary circuit configuration, and FIG. 10B illustrates waveforms of an input pulse signal INVᵢₙ and an output pulse signal INVₒᵤₜ.

FIG. 11 is a cross-sectional view illustrating an mounting structure of a display panel according to a referential example.

FIG. 12 is an enlarged plan view illustrating a schematic mounting state of the capacitive element.

FIG. 13 is a cross-sectional view illustrating an mounting structure of a display panel according to an embodiment of the present disclosure.

FIG. 14 is a perspective view illustrating an exterior of a television set according to an embodiment of the present disclosure.

FIGS. 15A and 15B are perspective views illustrating an exterior of a digital camera according to an embodiment of the present disclosure, in which FIG. 15A is a front perspective view, and FIG. 15B is a rear perspective view.

FIG. 16 is a perspective view illustrating an exterior of a laptop computer according to an embodiment of the present disclosure.

FIG. 17 is a perspective view illustrating an exterior of a video camera according to an embodiment of the present disclosure:

FIGS. 18A to 18G are exterior views illustrating a mobile phone according to an embodiment of the present disclosure, in which FIG. 18A is a front view in an open state, FIG. 18B is a side view thereof, FIG. 18C is a front view in a closed state, FIG. 18D is a left-side view, FIG. 18E is a right-side view, FIG. 18F is a top view, and FIG. 18G is a bottom view.

### DETAILED DESCRIPTION OF EMBODIMENTS

Embodiments of the present disclosure (hereinafter, referred to as “embodiments”) will now be described with reference to the accompanying drawings. The description will be made in the following sequence:

1. Organic EL Display Device in Embodiments of Present Disclosure
1-1. System Configuration
1-2. Basic Circuit Operation
1-3. Configuration Example of Drive Circuit Section

2. Description of Embodiments
2-1. Mounting Structure of Display Panel in Embodiments of Present Disclosure
2-2. Method of Manufacturing Display Panel in Embodiments of Present Disclosure

3. Modifications

4. Applications (Electronic Apparatus)

### 1. Organic EL Display Device in Embodiments of Present Disclosure

1-1. System Configuration

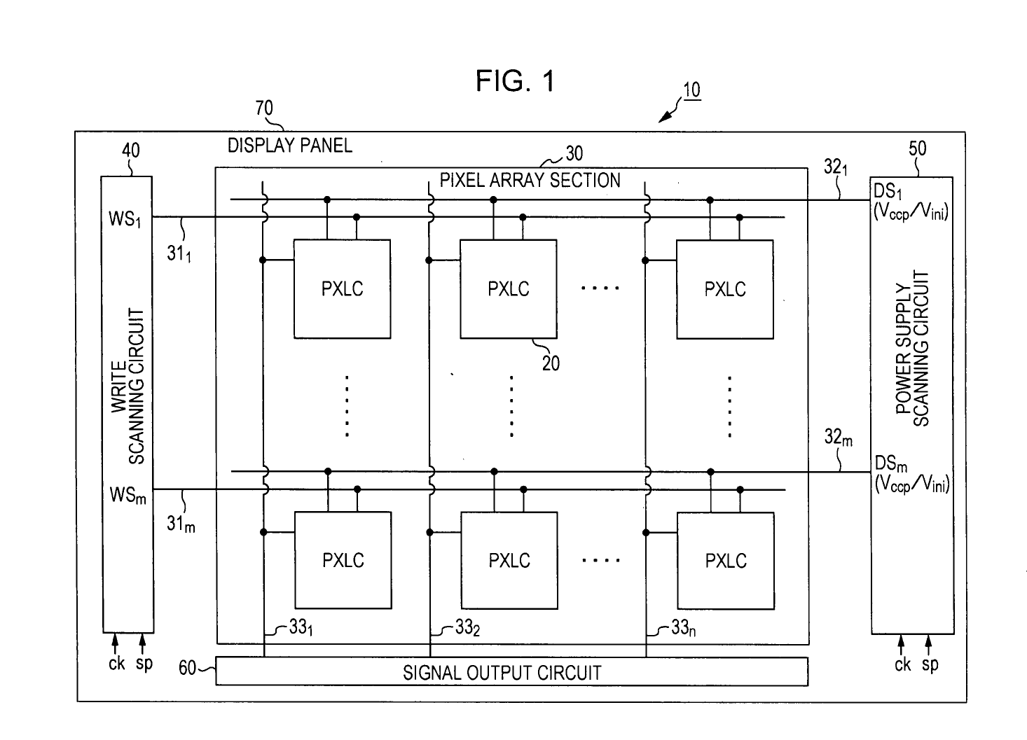

FIG. 1 is a system configuration diagram illustrating a schematic configuration of the active matrix type organic EL display device according to an embodiment of the present disclosure.

The active matrix type organic EL display device is a display device in which the electric current flowing through the organic EL element as a current-driven type electro-optical element is controlled by an active element such as an insulated gate field effect transistor, provided in the same pixel as that of the organic EL element. Typically, a TFT (thin-film transistor) is used as the insulated gate field effect transistor.

Referring to FIG. 1, the organic EL display device 10 according to an embodiment of the present disclosure includes a plurality of pixels 20 having organic EL elements, a pixel array section 30 in which the pixels 20 are arranged in a two-dimensional space in a matrix shape, and a drive circuit section arranged in the circumference of the pixel array section 30. The drive circuit section includes a write scanning circuit 40, a power supply scanning circuit 50, a signal output circuit 60, and the like to drive each pixel 20 of the pixel array section 30.

Here, in a case where the organic EL display device 10 has a color display correspondence, a single pixel (unit pixel) includes a plurality of sub-pixels, and each sub-pixel corresponds to the pixel 20 of FIG. 1. More specifically, in the case of the color display correspondence display device, a single pixel includes, for example, three sub-pixels including a sub-pixel emitting red light (R), a sub-pixel emitting green light (G), and a sub-pixel emitting blue light (B).

However, a structure of the sub-pixels included in a single pixel is not limited to the three primary colors RGB, and may a single pixel of a single color or a plurality of colors in addition to sub-pixels of three primary colors. More specifically, for example, a sub-pixel emitting white light (W) may be added to the single pixel in order to improve luminance. Alternatively, at least one sub-pixel emitting a complementary color light may be added to the single pixel in order to enlarge a color reproduction range.

In the pixel array section 30, the scanning lines 31₁ to 31ₘ and the power supply lines 32₁ to 32ₘ are arranged in each pixel row along the row direction (the arrangement direction of the pixels of the pixel row) in the array of pixels 20 of m rows and n columns. In addition, the signal lines 33₁ to 33ₙ are arranged in each pixel column along the column direction (the arrangement direction of the pixels of the pixel column).

Each scanning line 31₁ to 31ₘ is connected to the output terminal of the corresponding row of the write scanning circuit 40. Each power supply line 32₁ to 32ₘ is connected to the output terminal of the corresponding row of the power supply scanning circuit 50. Each signal line 33₁ to 33ₙ is connected to the output terminal of the corresponding column of the signal output circuit 60.

The pixel array section 30 is typically formed on a transparent insulation substrate such as a glass substrate. As a result, the organic EL display device 10 has a flat type panel structure. The drive circuit for each pixel 20 of the pixel array section 30 may be formed of an amorphous silicon TFT or a low-temperature poly-silicon TFT. In the case where the low-temperature poly-silicon TFT is used, as shown in FIG. 1, the write scanning circuit 40, the power supply scanning circuit 50, and the signal output circuit 60 may also be mounted in the display panel (substrate) 70 used to form the pixel array section 30.

The write scanning circuit 40 includes a shift register circuit or the like for shifting (transporting) the start pulse sp in sequence in synchronization with the clock pulse ck (the specific configuration of the write scanning circuit 40 will be described in detail below). When the image signal is written to each pixel 20 of the pixel array section 30, the write scanning circuit 40 sequentially scans each pixel 20 of the pixel array section 30 in the unit of a row by supplying the write scanning signal WS (WS₁ to WSₘ) to the scanning line 31 (31₁ to 31ₘ) in sequence (line progressive scanning).

The power supply scanning circuit 50 includes a shift register circuit or the like that sequentially shifts the start pulse sp in synchronization with the clock pulse ck. The power supply scanning circuit 50 supplies the power supply line 32 (32₁ to 32ₘ) with the power-supply electric potential DS (DS₁ to DSₘ) capable of switching to the first power-supply electric potential V_{ccp} and the second power-supply electric potential Vᵢₙᵢ lower than the first power-supply electric potential V_{ccp} in synchronization with the line progressive scanning of the write scanning circuit 40. As described below, light emission/non-emission of the pixel 20 is controlled based on the switching to V_{ccp}/Vᵢₙᵢ from the power-supply electric potential DS.

The signal output circuit 60 selectively outputs the signal voltage V_{sig} of the image signal corresponding to luminance information output from the signal supply source (not shown) (hereinafter, also referred to as a signal voltage) and a reference electric potential V_{ofs}. Here, the reference electric potential V_{ofs} is the electric potential serving as a reference of the signal voltage V_{sig} of the image signal (for example, the electric potential corresponding to a black level of the image signal) and is used in the threshold value correction process, which will be described below.

The signal voltage V_{sig}/reference electric potential V_{ofs} output from the signal output circuit 60 is written to each pixel 20 of the pixel array section 30 through the signal line 33 (33₁ to 33ₙ) in the unit of pixel row selected by the scanning of the write scanning circuit 40. That is, the signal output circuit 60 employs a line progressive writing type drive mode in which the signal voltage V_{sig} is written in the unit of a row (line).

Pixel Circuit

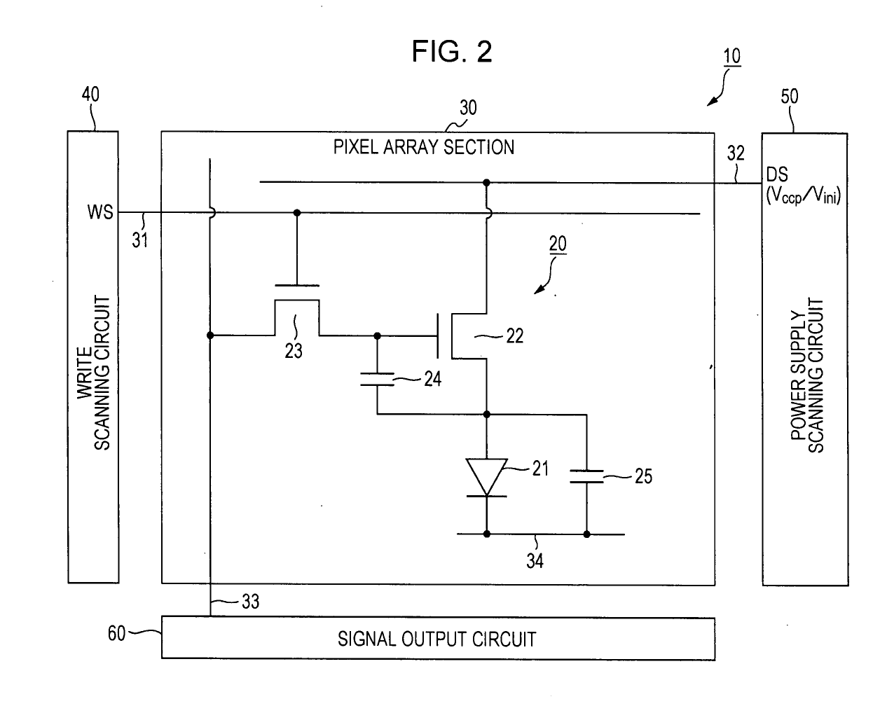

FIG. 2 is a circuit diagram illustrating an exemplary circuit configuration of the pixel (pixel circuit) 20 in detail. The light-emitting section of the pixel 20 includes an organic EL element 21 as a current-driven type electro-optic element in which luminance of emitted light changes depending on the electric current value flowing through a device.

Referring to FIG. 2, the pixel 20 includes an organic EL element 21 and a drive circuit for driving the organic EL element 21 by flowing the electric current through the organic EL element 21. The cathode of the organic EL element 21 is connected to the common power supply line 34 commonly wired for all of the pixels 20 (so called, beta-wiring).

The drive circuit for driving the organic EL element 21 includes a drive transistor 22, a write transistor 23, a storage capacitance 24, and a subsidiary capacitance 25. An N-channel type TFT may be used as the drive transistor 22 and the write transistor 23. However, conduction types of the drive transistor 22 and the write transistor 23 described herein are just exemplary, and are not intended to limit the scope of the present disclosure.

In the drive transistor 22, one electrode (source/drain electrode) is connected to the anode of the organic EL element 21, and the other electrode (drain/source electrode) is connected to the power supply line 32 (32₁ to 32ₘ).

In the write transistor 23, one electrode (source/drain electrode) is connected to the signal line 33 (33₁ to 33ₙ), and the other electrode (drain/source electrode) is connected to the gate electrode of the drive transistor 22. In addition, the gate electrode of the write transistor 23 is connected to the scanning line 31 (31₁ to 31ₘ).

In the drive transistor 22 and the write transistor 23, one electrode refers to a metal wiring line electrically connected to the source/drain area, and the other electrode refers to a metal wiring line electrically connected to the drain/source area. In addition, based on the electric potential relationship between one electrode and the other electrode, if one electrode also serves as the source electrode, it may serve as the drain electrode. If the other electrode serves as the drain electrode, it may serve as the source electrode.

In the storage capacitor 24, one electrode is connected to the gate electrode of the drive transistor 22, and the other electrode is connected to the other electrode of the drive transistor 22 and the anode of the organic EL element 21.

In the subsidiary capacitor 25, one electrode is connected to the anode of the organic EL element 21, and the other electrode is connected to the common power supply line 34. The subsidiary capacitor 25 is provided as necessary in order to supplement a shortfall of the capacitance of the organic EL element 21 and increase a write gain of the image signal for the storage capacitance 24. That is, the subsidiary capacitance 25 is not an indispensable element, and may be omitted if the equivalent capacitance of the organic EL element 21 is sufficiently high.

Although it has been described herein that the other electrode of the subsidiary capacitor 25 is connected to the common power supply line 34, the other electrode may be connected to any other node if it has a constant electric potential without limitation to the common power supply line 34. Since the other electrode of the subsidiary capacitor 25 is connected to the node having a constant electric potential, it is possible to achieve desired advantages such as supplementing a shortfall of the capacitance of the organic EL element 21 and increasing the write gain of the image signal for the storage capacitor 24.

In the pixel 20 having the aforementioned configuration, the write transistor 23 is turned on in response to the high active write scanning signal WS applied from the write scanning circuit 40 through the scanning line 31 to the gate electrode. As a result, the write transistor 23 samples the reference electric potential V_{ofs} or the signal voltage V_{sig} of the image signal corresponding to the luminance information supplied from the signal output circuit 60 through the signal line 33 and writes it to the pixel 20. The written signal voltage V_{sig} or the reference electric potential V_{ofs} is applied to the gate electrode of the drive transistor 22 and also stored in the storage capacitor 24.

When the power-supply electric potential DS of the power supply line 32 (32₁ to 32ₘ) is maintained at the first power-supply electric potential V_{ccp}, one electrode of the drive transistor 22 serves as the drain electrode, and the other electrode serves as the source electrode so that the drive transistor 22 operates at the saturation region. As a result, the drive transistor 22 receives an electric current supplied from the power supply line 32 and drives the organic EL element 21 with the electric current to emit light. More specifically, by operating the drive transistor 22 at the saturation region, the drive transistor 22 supplies the organic EL element 21 with the drive current having an electric current value corresponding to the voltage value of the signal voltage V_{sig} stored in the storage capacitor 24 and drives the organic EL element 21 with the electric current to emit light.

Furthermore, when the power-supply electric potential DS changes from the first power-supply electric potential V_{ccp} to the second power-supply electric potential Vᵢₙᵢ, one electrode of the drive transistor 22 serves as the source electrode, and the other electrode serves as the drain electrode so that the drive transistor 22 operates as a switching transistor. As a result, the drive transistor 22 stops supplying the organic EL element 21 with the drive current so that the organic EL element 21 is under a non light-emitting state. That is, the drive transistor 22 also serves as a transistor for controlling light emission/non-emission of the organic EL element 21.

Due to the switching operation of the drive transistor 22, a period for which the organic EL element 21 is maintained under the non light-emission state (non light-emission period) is provided so that a (duty) ratio between the light-emission period and no light-emission period of the organic EL element 21 can be controlled. By controlling the duty, it is possible to alleviate afterimage glimmering caused by the light emitted from the pixel for a single display frame period, and particularly, improve image quality of moving pictures.

Out of the first and second power-supply electric potentials V_{ccp} and Vᵢₙᵢ selectively supplied from the power supply scanning circuit 50 through the power supply line 32, the first power-supply electric potential V_{ccp} is a power-supply electric potential for supplying the drive transistor 22 with a drive current for driving light emission of the organic EL element 21. In addition, the second power-supply electric potential Vᵢₙᵢ is a power-supply electric potential for applying a reverse bias to the organic EL element 21. The second power-supply electric potential Vᵢₙᵢ is set to an electric potential lower than the reference electric potential V_{ofs}, for example, an electric potential lower than V_{ofs}−Vₜₕ, and preferably, sufficiently lower than V_{ofs}−Vₜₕ, where Vₜₕ denotes a threshold voltage of the drive transistor 22.

1-2. Basic Circuit Operation

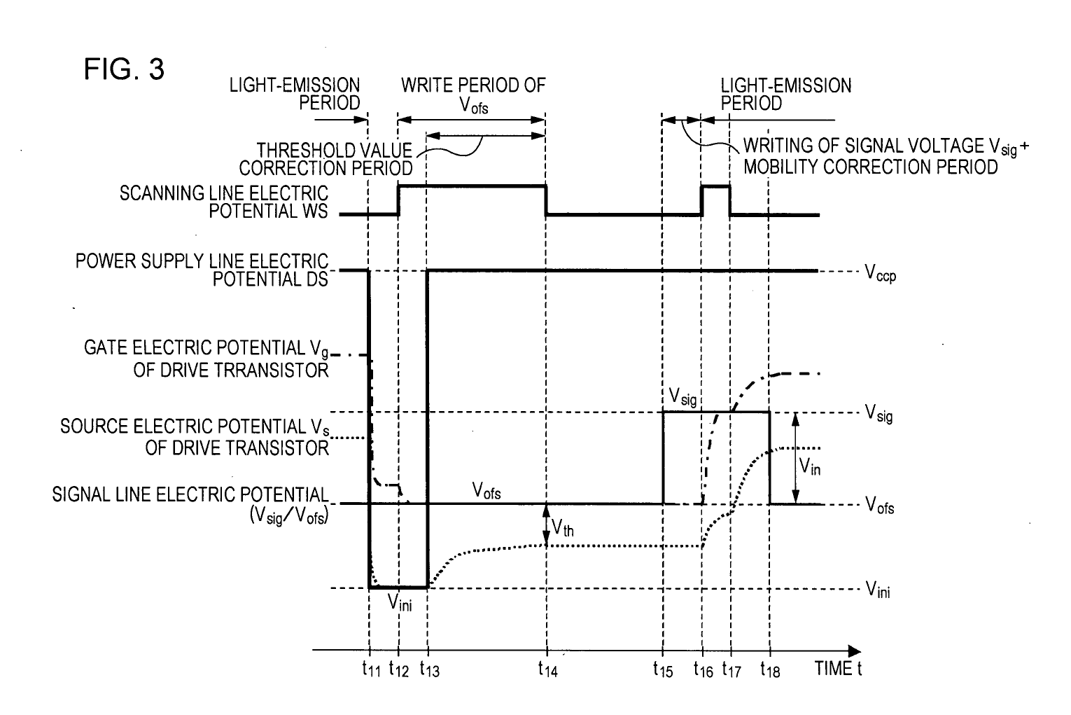

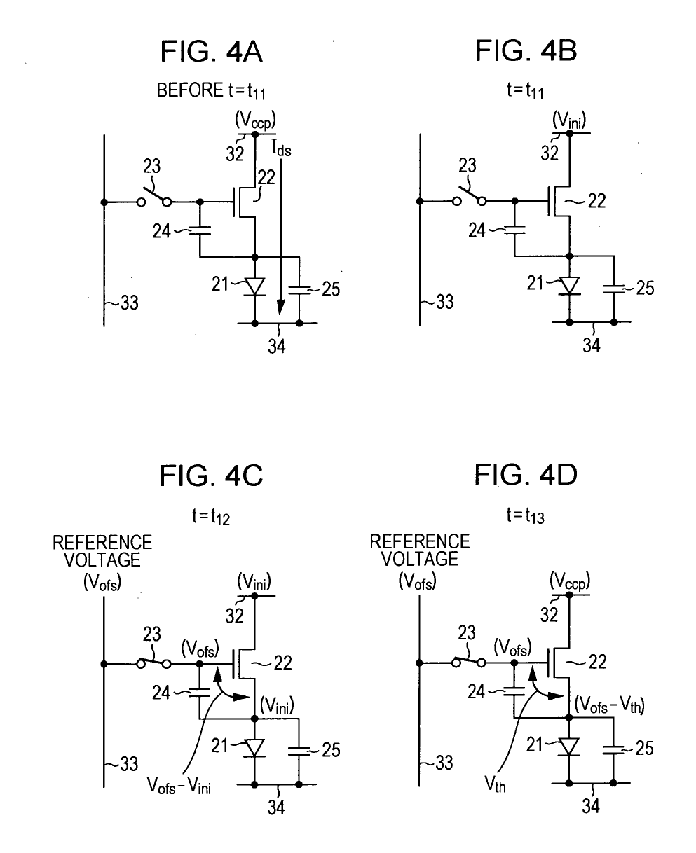

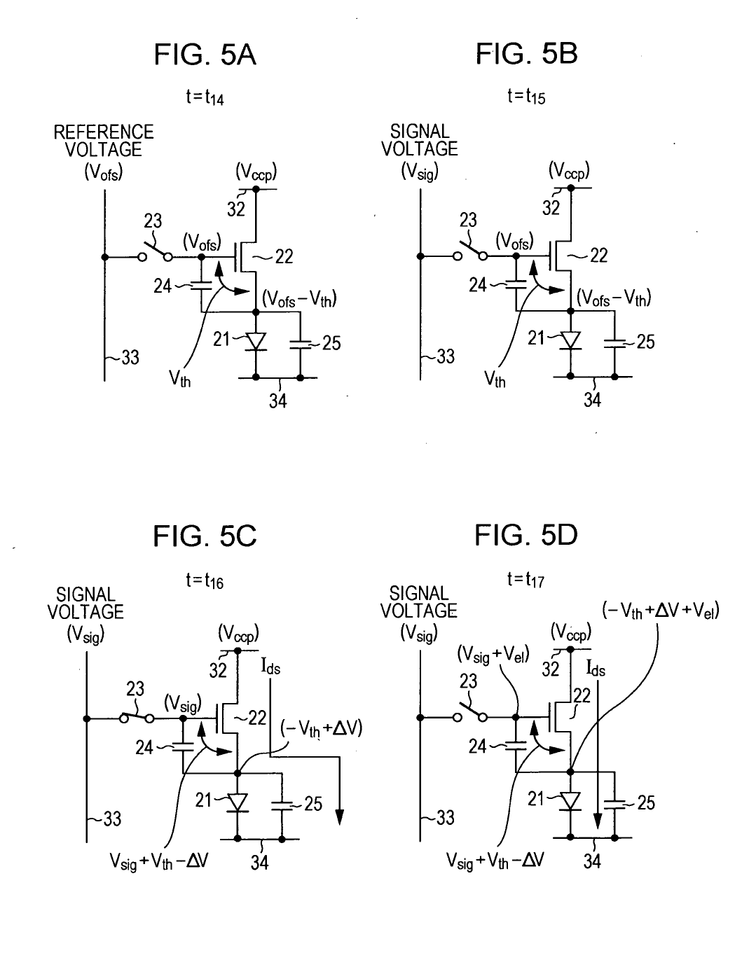

Subsequently, a basic circuit operation of the organic EL display device 10 having the aforementioned configuration will be described with reference to the timing waveform chart of FIG. 3 and operation explanatory diagrams of FIGS. 4A to 4D and 5A to 5D. In addition, in the operation explanatory diagrams of FIGS. 4A to 4D and 5A to 5D, the write transistor 23 is illustrated as a switch symbol for the purpose of simplicity of illustration.

The timing waveform chart of FIG. 3 shows the electric potential WS (write scanning signal) of the scanning line 31, the electric potential DS (power-supply electric potential) of the power supply line 32, the electric potential (V_{sig}/V_{ofs}) of the signal line 33, the gate electric potential V_{g} of the drive transistor 22, and the source electric potential Vₛ. In addition, the waveform of the gate electric potential V_{g} is denoted by a dashed-dotted line, and the waveform of the source electric potential Vₛ is denoted by a dotted line in order to distinguish them.

Light-Emission Period of Pre-Display Frame

In the timing waveform chart of FIG. 3, the period before the time t₁₁ corresponds to a light-emission period of the organic EL element 21 in a previous display frame. In the light-emission period of the previous display frame, the electric potential DS of the power supply line 32 is a first power-supply electric potential V_{ccp} (hereinafter, referred to as a “high electric potential”), and the write transistor 23 is turned off.

In this case, the drive transistor 22 is designed to operate at a saturation region. As a result, as shown in FIG. 4A, the drive electric current (drain-source current) I_{ds} corresponding to the gate-source voltage V_{gs} of the drive transistor 22 is supplied from the power supply line 32 to the organic EL element 21 through the drive transistor 22. As a result, the organic EL element 21 emits light with luminance corresponding to the electric current value of the drive electric current I_{ds}.

Threshold Value Correction Preparation Period

At the time t₁₁, a new display frame (current display frame) for a line progressive scanning is initiated. Then, as shown in FIG. 4B, the electric potential DS of the power supply line 32 switches from the high electric potential V_{ccp} to a second power-supply electric potential (hereinafter, referred to as a “low electric potential”) Vᵢₙᵢ sufficiently lower than V_{ofs}−Vₜₕ relative to the reference electric potential V_{df}, of the signal line 33.

Here, the threshold voltage of the organic EL element 21 is referred to as Vₜₕₑₗ, and the electric potential (cathode electric potential) of the common power supply line 34 is referred to as V_{cath}. In this case, if the low electric potential Vᵢₙᵢ is set to Vᵢₙᵢ<Vₜₕₑ₁+V_{cath}, the source electric potential Vₛ of the drive transistor 22 becomes approximately equal to the low electric potential V. Therefore, the organic EL element 21 is reverse-biased, and the light is turned off.

Next, at the time t₁₂, the electric potential WS of the scanning line 31 changes from the low electric potential to the high electric potential, and, as shown in FIG. 4C, the write transistor 23 is turned on. In this case, since the reference electric potential V_{ofs} has been supplied from the signal output circuit 60 to the signal line 33, the gate electric potential V_{g} of the drive transistor 22 is at the reference electric potential V_{ofs}. In addition, the source electric potential Vₛ of the drive transistor 22 is at an electric potential Vᵢₙᵢ sufficiently lower than the reference electric potential V_{ofs}.

In this case, the gate-source voltage V_{g}, of the drive transistor 22 becomes V_{ofs}−Vᵢₙᵢ. Here, if the voltage V_{ofs}<Vᵢₙᵢ is not higher than the threshold voltage Vₜₕ of the drive transistor 22, it is not possible to perform the threshold value correction process, which will be described below. Therefore, it is necessary to set an electric potential relationship to V_{ofs}−Vᵢₙᵢ>Vₜₕ.

In this manner, a process of performing initialization by fixing the gate electric potential V_{g} of the drive transistor 22 to the reference electric potential V_{ofs} and fixing (settling) the source electric potential Vₛ to the low electric potential Vᵢₙᵢ is the preparation process (threshold value correction preparation) before the threshold value correction process (threshold value correction operation), which will be described below. Therefore, the reference electric potential V_{ofs} and the low electric potential Vᵢₙᵢ become the initialization electric potentials of the gate electric potential V_{g} and the source electric potential Vₛ of the drive transistor 22, respectively.

Threshold Value Correction Period

Next, at the time t₁₃, as shown in FIG. 4D, as the electric potential DS of the power supply line 32 switches from the low electric potential Vᵢₙᵢ to the high electric potential V_{ccp}, the threshold value correction process is initiated while the gate electric potential V_{g} of the drive transistor 22 remains at the reference electric potential V_{ofs}. That is, the source electric potential Vₛ of the drive transistor 22 starts to rise to the electric potential obtained by subtracting the threshold voltage Vₜₕ of the drive transistor 22 from the gate electric potential V_{g}.

Here, for the purpose of simplicity, a threshold value correction process refers to a process of changing the source electric potential Vₛ to the electric potential obtained by subtracting the threshold voltage Vₜₕ of the drive transistor 22 from the initialization electric potential V_{ofs} with respect to the initialization electric potential V_{ofs} of the gate electric potential V_{g} of the drive transistor 22. As the threshold value correction process progresses, the gate-source voltage V_{gs} of the drive transistor 22 reaches the threshold voltage. Vₜₕ of the drive transistor 22. Such a voltage corresponding to the threshold voltage Vₜₕ is stored in the storage capacitor 24.

In addition, during the period for performing the threshold value correction process (threshold value correction period), the electric potential V_{cath} of the common power supply line 34 is set such that the organic EL element 21 has a cut-off state in order to flow the electric current only to the storage capacitance 24 side and prohibit the electric current from flowing to the organic EL element 21 side.

Next, at the time t₁₄, as the electric potential WS of the scanning line 31 changes to the low electric potential, the write transistor 23 is turned off as shown in FIG. 5A. In this case, the gate electrode of the drive transistor 22 is electrically disconnected from the signal line 33 so as to be in a floating state. However, since the gate-source voltage V_{gs} is equal to the threshold voltage Vₜₕ of the drive transistor 22, the drive transistor 22 is in a cut-off state. Therefore, the drain-source current I_{ds} does not flow to the drive transistor 22.

Signal Writing and Mobility Correction Period

Next, at the time t₁₅, as shown in FIG. 5B, the electric potential of the signal line 33 changes from the reference electric potential V_{ofs} to the signal voltage V_{sig} of the image signal. Subsequently, at the time t₁₆, as the electric potential WS of the scanning line 31 changes to the high electric potential, the write transistor 23 is turned on as shown in FIG. 5C, and the signal voltage V_{sig} of the image signal is sampled and written to the pixel 20.

As the signal voltage V_{sig} is written by the write transistor 23, the gate electric potential V_{g} of the drive transistor 22 becomes the signal voltage V_{sig}. When the drive transistor 22 is driven by the signal voltage V_{sig} of the image signal, the threshold voltage Vₜₕ of the drive transistor 22 is canceled by the voltage corresponding to the threshold voltage Vₜₕ stored in the storage capacitor 24. The principle of the threshold value canceling will be described below in detail.

In this case, the organic EL element 21 has a cut-off state (high impedance state). Therefore, the electric current (drain-source current I_{ds}) flowing from the power supply line 32 to the drive transistor 22 in response to the signal voltage V_{sig} of the image signal also flows to the subsidiary capacitor 25 and the equivalent capacitor of the organic EL element 21, which triggers charging of those capacitances.

As the subsidiary capacitor 25 and the equivalent capacitor of the organic EL element 21 are electrically charged, the source electric potential Vₛ of the drive transistor 22 gradually increases as time elapses. In this case, since deviations of the threshold voltages Vₜₕ of the drive transistors 22 between pixels have been already canceled, the drain-source current I_{ds} of the drive transistor 22 depends on mobility μ of the drive transistor 22. In addition, mobility μ of the drive transistor 22 is determined by mobility of the semiconductor thin-film included in the channel of the drive transistor 22.

Here, it is assumed that the ratio of the storage voltage V_{gs} of the storage capacitance 24 relative to the signal voltage V_{sig} of the image signal, that is, a writing gain G is set to 1 (ideal value). Then, the source electric potential Vₛ of the drive transistor 22 rises to the electric potential V_{ofs}−Vₜₕ+ΔV. Therefore, the gate-source voltage V_{gs} of the drive transistor 22 becomes V_{sig}−V_{ofs}+Vₜₕ−ΔV.

That is, the increment ΔV of the source electric potential Vₛ of the drive transistor 22 is subtracted from the voltage (V_{sig}−V_{ofs}+Vₜₕ) stored in the storage capacitance 24, that is, acts to discharge the electric charges of the storage capacitor 24 so that a negative feedback can be applied to the storage capacitor 24. Accordingly, the increment ΔV of the source electric potential Vₛ corresponds to the feedback amount of the negative feedback.

In this manner, since a negative feedback is applied to the gate-source voltage V_{gs} with the feedback amount ΔV corresponding to the drain-source current I_{ds} flowing through the drive transistor 22, it is possible to eliminate dependence on the mobility μ of the drain-source current I_{ds} of the drive transistor 22. This elimination process is the mobility correction process for correcting deviations of the mobility μ of the drive transistor 22 of each pixel.

More specifically, as a signal amplitude Vᵢₙ(=V_{sig}−V_{ofs}) of the image signal written to the gate electrode of the drive transistor 22 increases, the drain-source current I_{ds} increases. Accordingly, an absolute value of the feedback amount ΔV of the negative feedback increases. Therefore, a mobility correction process depending on the emitted light luminance level is carried out.

In addition, if the signal amplitude Vᵢₙ of the image signal is constant, the absolute value of the feedback amount ΔV of the negative feedback increases as mobility μ of the drive transistor 22 increases. Therefore, it is possible to remove deviations of the mobility μ between pixels. Accordingly, it can be said that the feedback amount ΔV of the negative feedback is the correction amount for the mobility correction process. The principle of the mobility correction will be described below in detail.

Light-Emission Period

Next, at the time t₁₇, as the electric potential WS of the scanning line 31 changes to the low electric potential, the write transistor 23 is turned off as shown in FIG. 5D. As a result, the gate electrode of the drive transistor 22 is electrically disconnected from the signal line 33 so as to be in a floating state.

Here, when the gate electrode of the drive transistor 22 is in a floating state, the storage capacitor 24 is connected between the gate and the source of the drive transistor 22. Therefore, the gate electric potential V_{g} also changes in conjunction with variations in the source electric potential Vₛ of the drive transistor 22. In this manner, such an operation that the gate electric potential V_{g} of the drive transistor 22 changes in conjunction with variations in the source electric potential Vₛ is a bootstrap operation by the storage capacitor 24.

As the gate electrode of the drive transistor 22 is in a floating state, and the drain-source current I_{ds} of the drive transistor 22 starts to flow to the organic EL element 21, the anode electric potential of the organic EL element 21 rises in response to the electric current I_{ds}.

When the anode electric potential of the organic EL element 21 is higher than Vₜₕₑ₁+V_{cath}, a drive electric current starts to flow to the organic EL element 21 so that the organic EL element 21 starts to emit light. In addition, the rise of the anode electric potential of the organic EL element 21 is not different from the rise of the source electric potential Vₛ of the drive transistor 22. In addition, as the source electric potential Vₛ of the drive transistor 22 increases, the gate electric potential V_{g} of the drive transistor 22 increases accordingly due to the bootstrap operation of the storage capacitance 24.

In this case, assuming that the bootstrap gain is set to 1 (ideal value), the increment of the gate electric potential V_{g} becomes equal to the increment of the source electric potential Vₛ. Therefore, during the light-emission period, the gate-source voltage V_{gs} of the drive transistor 22 remains constant at V_{sig}−V_{ofs}+Vₜₕ−ΔV. In addition, at the time t₁₈, the electric potential of the signal line 33 changes from the signal voltage V_{sig} of the image signal to the reference electric potential V_{ofs}.

Through a series of the aforementioned circuit operations, operations of the threshold value correction preparation process, the threshold value correction process, the writing process of the signal voltage V_{sig} (signal writing), and the mobility correction process are carried out within a single horizontal scanning period (1H). In addition, the signal writing process and the mobility correction process are carried out in parallel for the time t₁₆ to t₁₇.

Divisional Threshold Value Correction

While a driving method in which the threshold value correction process is performed only a single time has been described by way of example here, the scope of the present disclosure is, not limited by such a driving method. For example, it may be possible to employ a driving method (so called, divisional threshold value correction) in which the threshold value correction process is divisionally performed several times over a plurality of horizontal scanning periods followed by a period 1H in addition to the period 1H for which the threshold value correction process is performed along with the mobility correction and the signal writing process.

In such a driving method using the divisional threshold value correction, it is possible to obtain a sufficient time over a plurality of horizontal scanning periods as the threshold value correction period although a time that can be allocated to a single horizontal scanning period has been reduced due to an increased number of pixels alongside increasing high definition.

Principle of Threshold Value Cancellation

Here, the principle of the threshold value cancellation (that is, threshold value correction) in the drive transistor 22 will be described. Since the drive transistor 22 is designed to operate at a saturation region, it operates as a constant electric current source. As a result, the organic EL element 21 is supplied with a constant drain-source current (driving electric current) I_{ds} from the drive transistor 22 as following (1):

I_{ds}=(½)·μ(W/L)Cₒₓ(V_{gs}−Vₜₕ)² (1),

where, W denotes a channel width of the drive transistor 22, L denotes a channel length, and Cₒₓ denotes a gate capacitance per unit area.

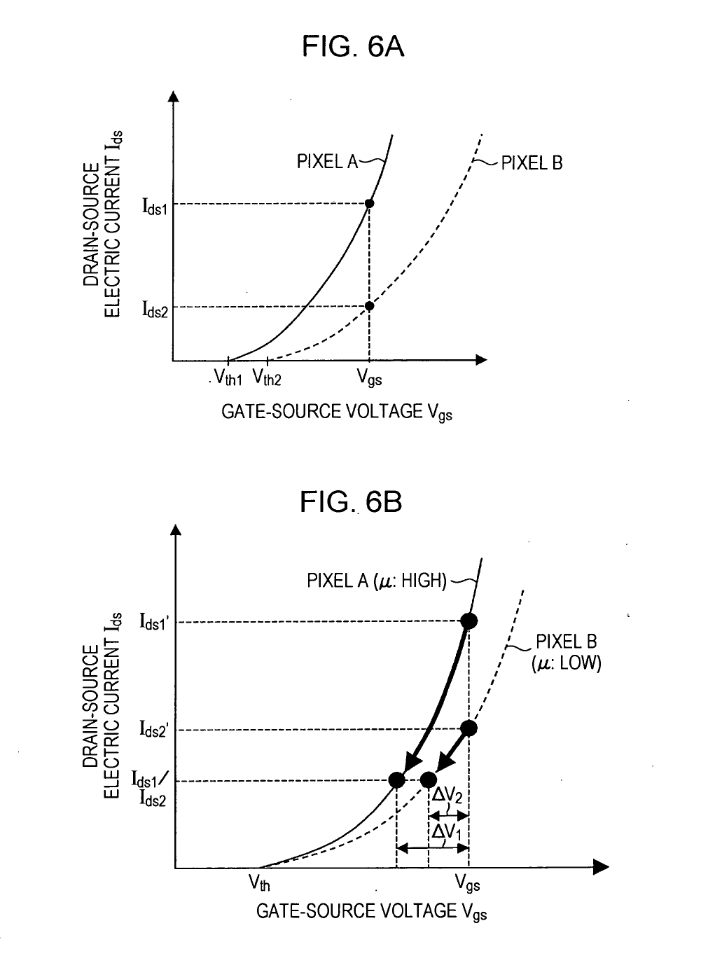

FIG. 6A illustrates a characteristic of the drain-source current I_{ds} versus the gate-source voltage V_{gs} of the drive transistor 22. As shown in the characteristic diagram of FIG. 6A, if the cancellation process (correction process) is not performed for deviations of the threshold voltages Vₜₕ of the drive transistors 22 between pixels, the drain-source current I_{ds} corresponding to the gate-source voltage V_{gs} becomes I_{ds1} when the threshold voltage Vₜₕ is at Vₜₕ₁.

In contrast, the drain-source current I_{ds} corresponding to the gate-source voltage V_{gs} becomes I_{ds2}(I_{ds2}<Vₜₕ₁) when the threshold voltage Vₜₕ is at Vₜₕ₂(Vₜₕ₂>Vₜₕ₁). That is, if the threshold voltage Vₜₕ of the drive transistor 22 changes, the drain-source current I_{ds} also changes even when the gate-source voltage V_{gs} remains constant.

Meanwhile, in the pixel (pixel circuit) 20 having the aforementioned configuration, the gate-source voltage V_{gs} of the drive transistor 22 during light emission is at V_{sig}−V_{ofs}+Vₜₕ−ΔV as described above. Therefore, if this value is applied to Equation (2), the drain-source current I_{ds} can be expressed as follows:

I_{ds}=(½)·μ(W/L)Cₒₓ(V_{sig}−V_{ofs}−ΔV)² (2).

That is, the term relating to the threshold voltage Vₜₕ of the drive transistor 22 is canceled, and the drain-source current I_{ds} supplied to the organic EL element 21 from the drive transistor 22 does not depend on the threshold voltage Vₜₕ of the drive transistor 22. As a result, the drain-source current I_{ds} does not change even when the threshold voltage Vₜₕ of the drive transistor 22 changes in each pixel due to deviations of the manufacturing process of the drive transistor 22 or aging variation. Therefore, it is possible to constantly maintain luminance of the light emitted from the organic EL element 21.

Principle of Mobility Correction

Next, the principle of mobility correction of the drive transistor 22 will be described. FIG. 6B illustrates a characteristic curve for comparing a pixel A of which the drive transistor 22 has relatively high mobility μ with another pixel B of which the drive transistor 22 has relatively low mobility μ. When the drive transistor 22 is made of a poly-silicon thin-film transistor or the like, mobility μ is unavoidably deviated between pixels as in the pixels A and B.

A case where a signal amplitude Vᵢₙ(=V_{sig}−V_{ofs}) with the same level is written to the gate electrodes of the drive transistors 22 of both pixels A and B while mobility μ is deviated between the pixels A and B is considered. In this case, a large difference is generated between the drain-source current I_{ds1}′ flowing through the pixel A having high mobility μ and the drain-source current I_{ds2}′ flowing through the pixel B having low mobility μ if no correction for the mobility μ is carried out. In this manner, if a large difference is generated between the drain-source currents I_{ds} due to deviations of mobility μ in each pixel, uniformity of display would be degraded.

Here, as apparent from the transistor characteristic Equation (1) described above, as mobility μ increases, the drain-source current I_{ds} increases. Therefore, the feedback amount ΔV of the negative feedback also increases as mobility μ increases. As shown in FIG. 6B, the feedback amount ΔV of the pixel A having high mobility μ is relatively higher than the feedback amount ΔV₂ of the pixel B having low mobility μ.

In this regard, the negative feedback is more strongly applied as mobility μ increases by applying a negative feedback to the gate-source voltage V_{gs} with a feedback amount ΔV with the drain-source current I_{ds} of the drive transistor 22 through the mobility correction process. As a result, it is possible to suppress deviations of mobility μ between pixels.

Specifically, if correction is made for the feedback amount ΔV₁ in the pixel A having high mobility the drain-source current I_{ds} remarkably decreases from I_{ds1}′ to I_{ds1}. Meanwhile, since the feedback amount ΔV₂ of the pixel B having low mobility μ is low, the drain-source current I_{ds} decreases from I_{ds2}′ to I_{ds2}, which is not significant. As a result, since the drain-source current I_{ds1} of the pixel A is approximately equal to the drain-source current I_{ds2} of the pixel B, the deviation in mobility μ between pixels is corrected.

In summary, in the case of the pixels A and B having different mobility μ, the feedback amount ΔV₁ of the pixel A having high mobility μ becomes comparatively higher than the feedback amount ΔV₂ of the pixel B having low mobility μ. That is, as mobility μ of the pixel increases, the feedback amount ΔV increases, and a decrement of the drain-source current I_{ds} increases.

Therefore, by applying a negative feedback to the gate-source voltage V_{gs} with the feedback amount ΔV corresponding to the drain-source current I_{ds} of the drive transistor 22, the electric current values of the drain-source currents I_{ds} of the pixels having different mobility μ are equalized. As a result, it is possible to correct deviations of mobility μ between pixels. That is, the process of applying a negative feedback to the gate-source voltage V_{gs} of the drive transistor 22, that is, the storage capacitance 24 with a feedback amount (correction amount) ΔV corresponding to the electric current (drain-source current I_{ds}) flowing through the drive transistor 22 is the mobility correction process.

1-3. Configuration Example of Drive Circuit Section

Here, a configuration example of the drive circuit section arranged in the circumference of the pixel array section 30 will be described. Here, a write scanning circuit 40 for sequentially and selectively scanning each pixel 20 in the unit of row when writing the signal voltage V_{sig} to each pixel 20 of the drive circuit section, for example, the pixel array section 30 will be exemplarily described.

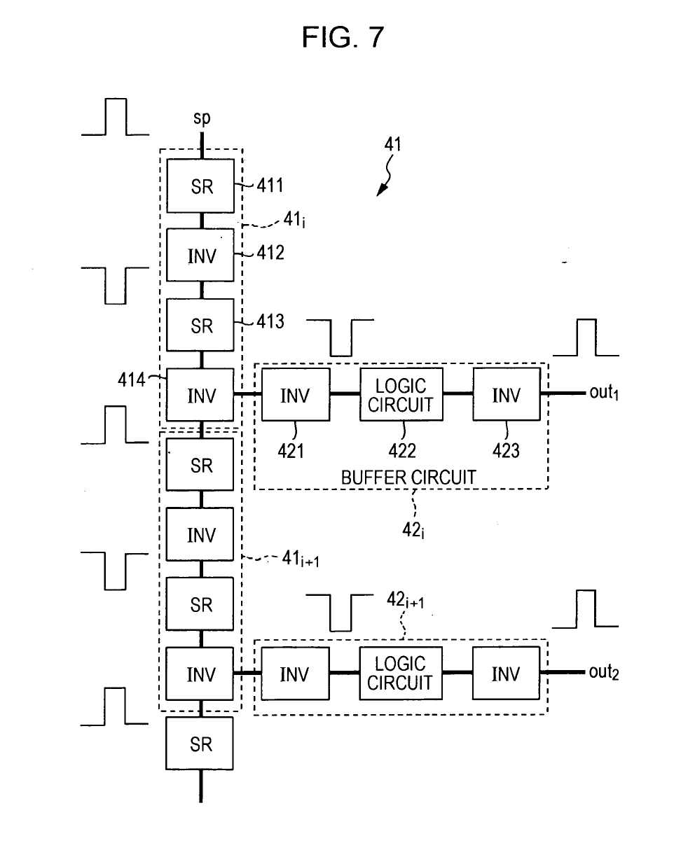

FIG. 7 is a block diagram illustrating an exemplary configuration of the write scanning circuit 40. Basically, the write scanning circuit 40 includes a shift register circuit 41, as a main component, for sequentially shifting (transferring) the start pulse sp in synchronization with a clock pulse ck (not shown). In addition, the write scanning circuit 40 includes buffer circuits 42ᵢ and 42ᵢ₊₁ in each transfer stage (unit circuit) 41ᵢ and 41ᵢ₊₁ of the shift register circuit 41 for each row of the pixel array section 30.

While a configuration in which two transfer stages 41ᵢ and 41ᵢ₊₁ are connected in cascade as the shift register circuit 41 is illustrated here, in practice, the transfer stages 41₁ to 41ₘ corresponding to the number of rows of the pixel array section 30 are connected in cascade. Each transfer stage of the shift register circuit 41, for example, the transfer stage 41ᵢ constitutes a unit circuit by connecting a shift register (SR) 411, an inverter (INV) 412, a shift register 413, and an inverter 414 in cascade.

In addition, the buffer circuit 42ᵢ is configured by connecting an inverter 421, a logic circuit 422, and an inverter 423 in cascade. In this manner, each of the transfer stages 41ᵢ and 41ᵢ₊₁ of the shift register circuit 41 and each of the buffer circuits 42 (42ᵢ and 42ᵢ₊₁) are configured using an inverter circuit.

Circuit Operation of Shift Register Circuit

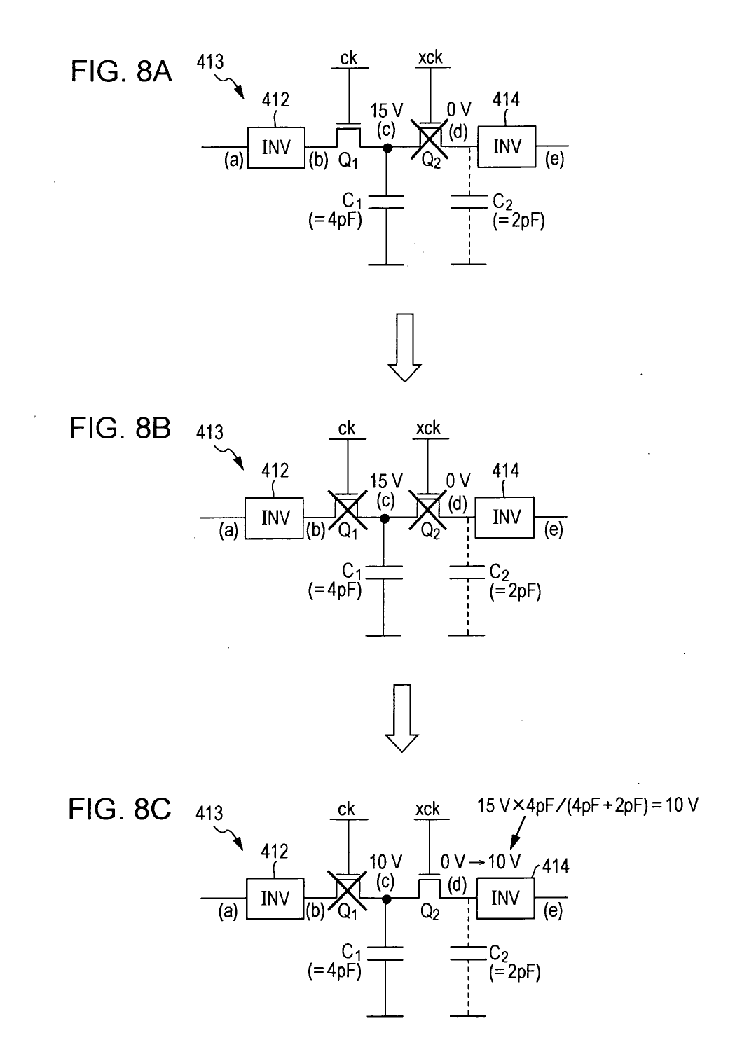

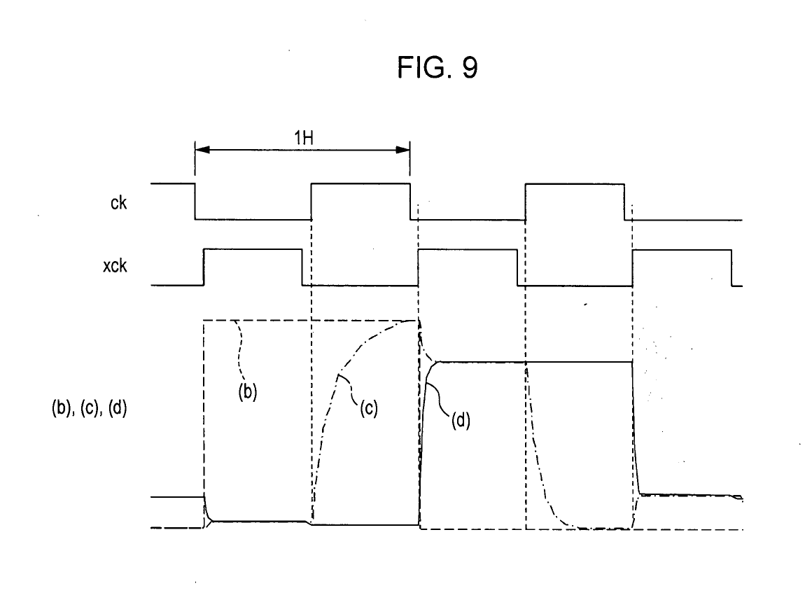

Here, a circuit operation of the shift register circuit 41 as a main component of the write scanning circuit 40 will be described with reference to the operation explanatory diagrams of FIGS. 8A to 8C and the timing waveform chart of FIG. 9. Here, the circuit operation of the circuit part of the inverter 412, the shift register 413, and the inverter 414 of the transfer stage 41ᵢ will be exemplarily described as the circuit operation of the shift register circuit 41.

The shift register 413 includes a transistor Qᵢ operated in synchronization with the clock pulse ck, a transistor Q₂ operated in synchronization with the clock pulse xck, and a capacitance C₁. In addition, it is assumed that a parasitic capacitance C₂ is exists between an input terminal of the inverter 414 and an output terminal of the shift register 413.

The timing waveform chart of FIG. 9 illustrates waveforms of the clock pulse ck, the clock pulse xck, the output voltage (b) of the inverter 412, the charged voltage (c) of the capacitance C₁, and the input voltage (d) of the inverter 414. The clock pulses ck and xck represent a pulse signal with a cycle of 1H. In both the clock pulses ck and xck, the active (high electric potential) period is slightly longer than the inactive (low electric potential) period. In addition, when one of the clock pulses ck and xck is activated, the other is deactivated.

In the operation explanatory diagrams of FIGS. 8A to 8C, if any one of the transistors Q₁ and Q₂ of the shift register 413 is turned off, the symbol X is put thereon. It is assumed that the amplitude (crest value) of the input voltage (A) of the inverter 412 is set to, for example, 15 V.

First, when the clock pulse ck is activated, the output voltage (b) of the inverter 412 having an amplitude of 15 V is charged in the capacitor C₁ via the transistor Q₁ having a turned-on state. In this case, since the clock pulse xck is deactivated, the transistor Q₂ is turned off as indicated by the symbol X (refer to FIG. 8A). In addition, as the clock pulse ck is deactivated, both the transistors Q₁ and Q₂ are turned off for a short period. As a result, a voltage (c) of 15 V is stored in the capacitor C₁ (refer to FIG. 8B).

Next, as the clock pulse xck is activated, a voltage (c) of 15 V stored in the capacitor C₁ is applied as an input voltage (d) to the inverter 414 via the transistor Q₂. In this case, since the parasitic capacitance C₂ is disposed between the output terminal of the shift register 413 and the input terminal of the inverter 414, an amplitude of the input voltage (d) of the inverter 414 decreases due to capacitance dividing between the capacitance C₁ and the parasitic capacitance C₂ (refer to FIG. 8C).

For example, assuming that the capacitance Cᵢ is set to 4 pF, and the parasitic capacitance C₂ is set to 2 pF, the capacitance is divided such that 15V×4 pF/(4 pF+2 pF) so that an amplitude of 15 V is reduced to an amplitude of 10 V. As a result, for the input voltage (a) having an amplitude of 15 V, it is possible to obtain an output voltage (e) having an amplitude of 10 V with a shift of 1 H.

Inverter Circuit of Single Channel Transistor

On the other hand, for a process of manufacturing the drive circuit section such as the write scanning circuit 40, it is possible to reduce manufacturing costs if the drive circuit section is configured using a single-channel (only N-channel or P-channel) transistors in comparison with using both channel transistors. Therefore, in order to reduce manufacturing costs of the organic EL display device 10, it is preferable that the inverter circuits included in the shift register circuit 41 or the buffer circuit 42, for example, in the write scanning circuit 40 are configured using single-channel transistors.

In addition, when the inverter circuit is configured using a single-channel transistor, a circuit configuration obtained by combining the single-channel transistor with a capacitive element is employed in order to guarantee a reliable circuit operation of the inverter circuit. Hereinafter, an inverter circuit obtained by combining the single-channel transistor with the capacitive element will be described.

Circuit Configuration

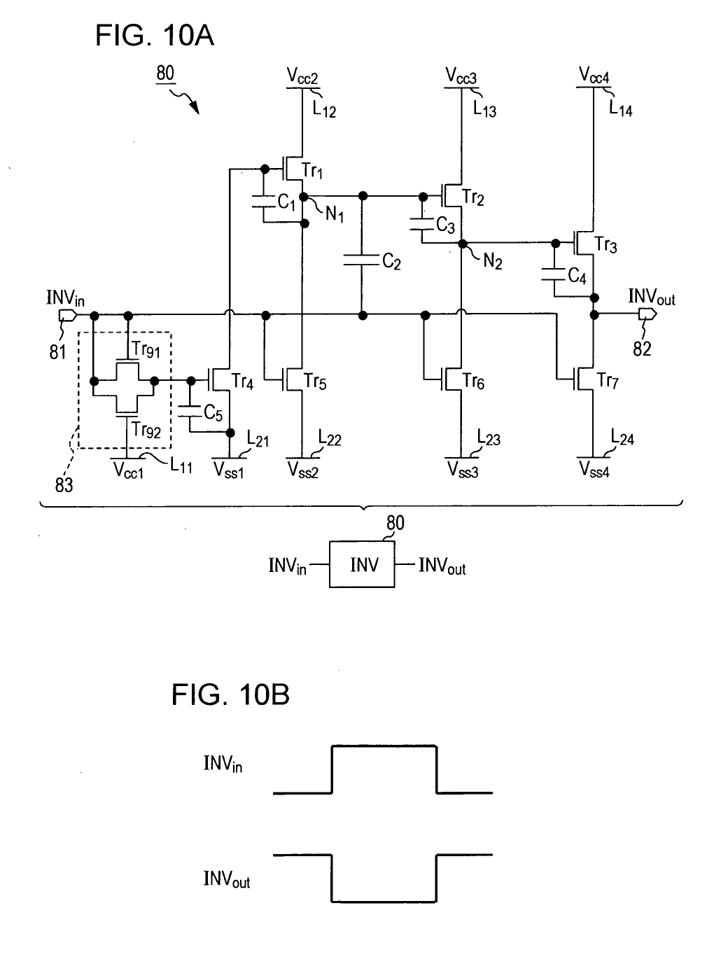

FIGS. 10A and 10B are explanatory diagrams illustrating an inverter circuit obtained by combining the single-channel transistor with the capacitive element, where FIG. 10A illustrates an exemplary circuit configuration, and FIG. 10B illustrates each waveform of the input and output pulse signals INVᵢₙ and INVₒᵤₜ

The inverter circuit 80 according to the present circuit example almost inverts the pulse signal INVᵢₙ input through the input terminal 81 and outputs from the output terminal 82 the pulse signal INVₒᵤₜ having a reversed phase relative to the pulse signal INVᵢₙ. As a power voltage, the inverter circuit 80 uses, for example, four power voltages V_{cc1}, V_{cc2}, V_{cc3}, and V_{cc4} for a positive side and, for example, four power voltages Vₛₛ₁, Vₛₛ₂, Vₛₛ₃, and Vₛₛ₄ for a negative side. However, the power voltages described herein are just exemplary, and are not intended to limit the scope of the present disclosure. A smaller number of power voltages may be used, or a single type of power voltage may be used in each of the positive and negative sides.

The inverter circuit 80 includes, for example, seven transistors Tr₁ to Tr₇, five capacitive elements C₁ to Cyᵣ and a delay circuit 83. The seven transistors Tr₁ to Tr₇ are made of the same (single) channel type, for example, N-channel MOS (metal oxide semiconductor) type thin-film transistors (TFTs). While only the N-channel transistors are used for the transistors Tr₁ to Tr₇ herein, only the P-channel transistors may also be used.

The transistor Tr₁ corresponds to a first transistor, and has a drain electrode connected to the power line L₁₂ of the positive-side power voltage V_{cc2} and a source electrode connected to the node N₁, so that a voltage corresponding to the input voltage (pulse signal INVᵢₙ) input through the input terminal 81 is used as a gate input. The transistor Tr₂ has a drain electrode connected to the power line L₁₃ of the positive-side power voltage V_{cc3} and a source electrode connected to the node N₂ and a gate electrode connected to the node N₁. The transistor Tr₁ has a drain electrode connected to the power line L₁₄ of the positive-side power voltage V_{cc4}, a source electrode connected to the output terminal 82, and a gate electrode connected to the node N₂.

The delay circuit 83 includes, for example, two transistors Tr₉₁ and Tr₉₂ connected in parallel. Naturally, the two transistors Tr₉₁ and Tr₉₂ are N-channel MOS transistors that are the same as the transistors Tr₁ to Tr₇. One of the commonly connected electrodes (source electrode/drain electrode) of the transistors Tr₉₁ and Tr₉₂ serves as a circuit input terminal of the delay circuit 83, and the other electrode (drain electrode/source electrode) serves as an circuit output terminal of the delay circuit 83.

In the delay circuit 83, the circuit input terminal is connected to the input terminal 81. The gate electrode of the transistor Tr₉₁ is also connected to the input terminal 81. The gate electrode of the transistor Tr₉₂ is connected to the power line L₁₁ of the positive-side power voltage V_{cc1}.

The transistor Tr₄ has a drain electrode connected to the gate electrode of the transistor Tr₁, a source electrode connected to the power line L₂₁ of the negative side power voltage Vₛₛ₁, and a gate electrode connected to the circuit output terminal of the delay circuit 83. The transistor Tr₅ corresponds to a second transistor, and has a drain electrode connected to the node N₁ and a source electrode connected to the power line L₂₂ of the negative side power voltage Vₛₛ₂. That is, the transistor Tr₅ is connected in series, and its gate electrode is connected to the input terminal 81.

The transistor Tr₆ has a drain electrode connected to the node N₂, a source electrode connected to the power line L₂₃ of the negative side power voltage Vₛₛ₃. That is, the transistor Tr₆ is connected in series with transistor Tr₂, and has a gate electrode connected to the input terminal 81. The transistor Tr₇ has connected a drain electrode to the output terminal 82, a source electrode connected to the power line L₂₄ of the negative side power voltage Vₛₛ₄, and a gate electrode connected to the input terminal 81.

The capacitive element C₁ corresponds to a first capacitive element, of which one electrode is connected to the gate electrode of the transistor Tr₁, and the other electrode is connected to the node N₁. That is, the capacitive element C₁ is connected between the gate and source of the transistor Tr₁. The capacitive element C₂ corresponds to a second capacitive element, of which one of the electrode is connected to the node N₁, and the other electrode is connected to the input terminal 81. The node N₁ is also a common node between the transistors Tr₁ and Try.

One electrode of the capacitive element C₃ is connected to the gate electrode of the transistor Tr₂, and the other electrode is connected to the node N₂. One electrode of the capacitive element C₄ is connected to the gate electrode of the transistor Tr₃, and the other electrode is connected to the output terminal 82. One electrode of the capacitive element C₅ is connected to the gate electrode of the transistor Tr₄, and the other electrode is connected to the power line L₂₁ of the negative side power voltage Vₛₛ₁.

Here, the delay circuit 83 including the transistors Tr₉₁ and Tr₉₂ serves as a high-resistance element connected between the input terminal 81 and the gate electrode of the transistor Tr₄. As a result, as the pulse signal INVᵢₙ input through the input terminal 81 passes through the delay circuit 83, a variation of the electric potential of the pulse signal INVᵢₙ is temporally delayed and delivered to the gate electrode of the transistor Tr₄. The delay amount of the delay circuit 83 can be controlled by changing a voltage value of the positive-side power voltage V_{cc1} and a capacitance value of the capacitive element C₅.

The transistor Tr₁ electrically connects or disconnects the node N₁ and the power line L₁₂ of the positive-side power voltage V_{cc2} depending on the voltage between the terminals of the capacitive element C₁. The transistor Tr₂ electrically connects or disconnects the node N₂ and the power line L₁₃ of the positive-side power voltage V_{cc3} depending on a difference between the electric potentials of the nodes N₁ and N₂, that is, a voltage between both terminals of the capacitive element C₃. The transistor Tr₁ electrically connects or disconnects the output terminal 82 and the power line L₁₄ of the positive-side power voltage V_{cc4} depending on a difference between the electric potentials of the node N₂ and the output terminal 82, that is, a voltage between both terminals of the capacitive element C₄.

The transistor Tr₄ electrically connects or disconnects the gate electrode of the transistor Tr₁ and the power line L₂₁ of the negative side power voltage Vₛₛ₁ depending on a difference between the electric potentials of the output terminal of the delay circuit 83 and the negative side power voltage Vₛₛ₁, that is, a voltage between both terminals of the capacitive element C₅. The transistor Try electrically connects or disconnects the node N₁ and the power line L₂₂ of the negative side power voltage Vₛₛ₂ depending on a difference between the electric potentials of the input terminal 81 and the negative side power voltage Vₛₛ₂. The transistor Tr₆ electrically connects or disconnects the node N₂ and the power line L₂₃ of the negative side power voltage Vₛₛ₃ depending on a difference between the electric potential of the input terminal 81 and the negative side power voltage Vₛₛ₃. The transistor Tr₁ electrically connects or disconnects the output terminal 82 and the power line L₂₄ of the negative side power voltage Vₛₛ₄ depending on a difference between the electric potential of the input terminal 81 and the negative side power voltage Vₛₛ₄.

Circuit Operation

Next, a circuit operation of the inverter circuit 80 having the aforementioned configuration when the pulse signal INVᵢₙ input through the input terminal 81 is activated (having a high electric potential state) and deactivated (having a low electric potential state) will be described.

When Pulse Signal INVᵢₙ is Activated:

As the pulse signal INVᵢₙ is activated, the gate electric potential of the transistor Tr₈ comes to be in a high electric potential state, and the transistor Tr₈ is turned on. Therefore, the negative side power voltage Vₛₛ₄ is output as the pulse signal INVₒᵤₜ from the output terminal 82. At the same time, since the transistors Tr₆ and Tr₇ are also turned on, the electric potentials of the nodes N₁ and N₂ are fixed to the negative side power-supply electric potentials Vₛₛ₂ and Vₛₛ₃, respectively.

As a result, both the transistors Tr₂ and Tr₃ are turned off. In addition, since the transistor Tr₄ is turned on in response to the delayed output of the delay circuit 83, the gate electric potential of the transistor Tr₁ is fixed to the negative side power voltage Vₛₛ₁. As a result, the transistor Tr₁ is also turned off. That is, when the pulse signal INVᵢₙ is activated, all of the transistors Trₗ, Tr₂ and Tr₃ of the positive side are turned off.

When Pulse Signal INVᵢₙ is Deactivated:

As the pulse signal INVᵢₙ is deactivated, at the same time, all of the transistors Tr₅, Tr₆, and Tr₇ of the negative electric potential side are turned off. In addition, the electric potential of the node N₁, that is, the gate electric potential of the transistor Tr₂ decreases due to a capacitive coupling of the capacitive element C₂ depending on a variation when the pulse signal INVᵢₙ is changed from a high electric potential to a low electric potential.

At the moment that the electric potential falls by the capacitive coupling, the gate electric potential of the transistor Tr₄ remains at a high electric potential state due to the delay in the delay circuit 83. Therefore, the gate electric potential of the transistor Tr₁ remains at the negative side power voltage Vₛₛ₁. Therefore, when the gate-source voltage V_{gs} of the transistor Tr₁ increases over the threshold voltage as the electric potential of the node N₁ falls, the transistor Tr₁ is turned on. As a result, the electric potential of the node N₁ increases up to the positive-side power voltage V_{cc1}.

Then, since the gate-source voltage V_{gs} of the transistor Tr₂ also increases, the transistor Tr₂ is also turned on. As a result, the electric potential of the node N₂ increases up to the positive-side power voltage V_{cc2}, and the gate-source voltage V_{gs} of the transistor Tr₃ also increases. Therefore, the transistor Tr₃ as well as the transistor Tr₂ is turned on. In addition, since the transistor Tr₃ is turned on, the positive-side power voltage V_{cc4} is output as the pulse signal INVₒᵤₜ from the output terminal 82.

Here, in order to more rapidly turn on the transistor Tr₁ as the gate electric potential of the transistor Tr₂ falls due to the capacitive coupling of the capacitive element C₂, it is preferable that the capacitance value of the capacitive element C₂ is set to a high level to some extent. In addition, since the transistor Tr₁ is rapidly turned on, it is possible to more precisely determine the transition timing (rising/falling timing) of the pulse signal INVₒᵤₜ.

The transition timing of the pulse signal INVₒᵤₜ determines the pulse width of the pulse signal INVₒᵤₜ. In addition, when the drive circuit section is the write scanning circuit 40, the pulse signal INVₒᵤₜ is used as a reference signal for generating the write scanning signal WS. Therefore, the pulse width of the pulse signal INVₒᵤₜ serves as a reference for determining the pulse width of the write scanning signal WS and also a reference for determining the operation time of the mobility correction process described above, that is, the mobility correction time.

Here, comparing long and short optimal mobility correction times, even when the same amount (time) of deviation is present in the pulse width of the write scanning signal WS, the deviation of the pulse width of the write scanning signal WS becomes relatively large in the case where an optimal mobility correction time is shorter. In addition, the deviation of the pulse width of the write scanning signal WS also causes a deviation of luminance, which degrades image quality. From this point of view, it is important to more precisely determine the transition timing of the pulse signal INVₒᵤₜ serving as a reference for determining the mobility correction time by setting a large capacitance value to the capacitive element C₂ to more rapidly turn on the transistor Tr₁.

As apparent from the aforementioned description of the circuit operation, in order to guarantee a reliable circuit operation of the inverter circuit 80 including the single-channel transistor, it is indispensable to include a capacitive element C₂ for decreasing the electric potential of the node N₁, particularly, using a capacitive coupling. In addition, in addition to the capacitive element C₂, it is also necessary to include capacitive elements C₁, C₃, and C₄ for storing the gate-source voltage V_{gs} of the transistors Tr₁, Tr₂, and Tr₇. Such capacitive elements C₁ to C₄ are not necessary in the inverter circuit including two-channel transistors.

The inverter circuit 80 obtained by combining a single-channel transistor with a capacitive element can be used as an inverter 412 or 414 included in the shift register circuit 41 of the write scanning circuit 40 shown in FIG. 7 or an inverter 421 or 423 included in the buffer circuit 42. Since the power supply scanning circuit 50 basically has the same configuration as that of the write scanning circuit 40, the inverter circuit 80 also can be used as an inverter of the power supply scanning circuit 50.

Problems in Mounting Single-Channel Transistor Inverter Circuit in Display Panel

If the drive circuit section such as the write scanning circuit 40 is configured using the inverter circuit 80 obtained by combining the single-channel transistor with the capacitive element, the number of capacitive elements used in the entirety of the drive circuit section significantly increases. In this regard, a case where the display panel 70 is configured by mounting the drive circuit section having a configuration according to an embodiment of the present disclosure and the pixel array section 30 in the same substrate will be reviewed.

Mounting Structure of Display Panel in Referential Example

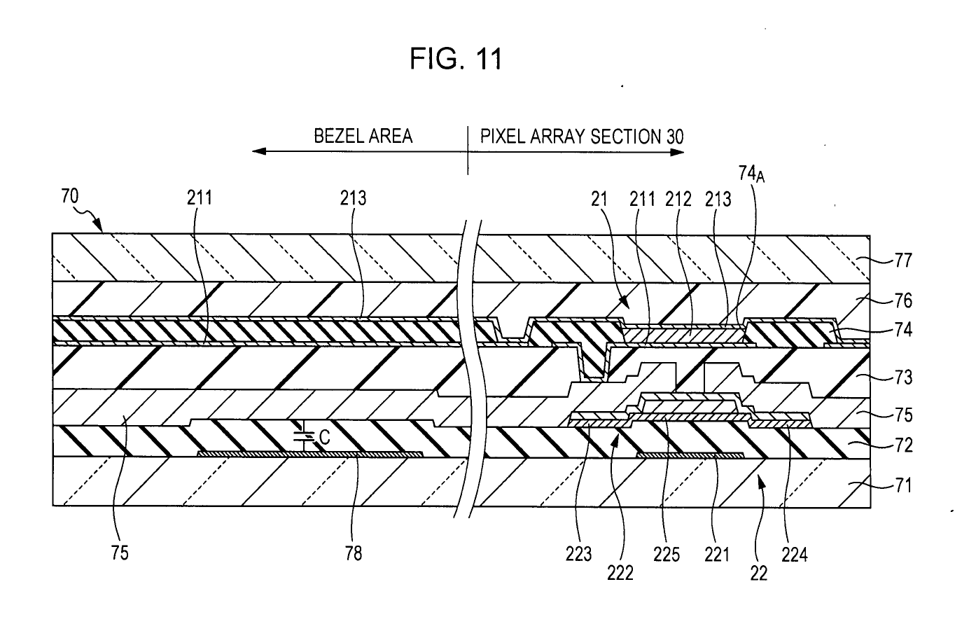

FIG. 11 is a cross-sectional view illustrating an mounting structure of the display panel according to a referential example. FIG. 11 shows cross-sectional structures of the pixel array section 30 and the bezel area which is a circumferential portion of the display panel 70.

Referring to FIG. 11, a circuit part including the drive transistor 22 and the like is formed over the glass substrate 71, and the organic EL element 21 is formed over the circuit part. Specifically, an insulation film 72, an insulation flattening film 73, and a wind insulation film 74 are sequentially formed on the glass substrate 71. Then, the organic EL element 21 is formed in a concave portion 74_{A} of the wind insulation film 74. Here, representative of a circuit part (a drive circuit) of the pixel 20 formed in an underlying layer of the organic EL element 21, that is, the layer facing the light-emission surface of the organic EL element 21, only the drive transistor 22 is illustrated, and other components are omitted.

The organic EL element 21 includes an anode 211, an organic layer 212, and a cathode 213. The anode 211 is formed of metal or the like on the bottom of the concave portion 74_{A} of the wind insulation film 74. The organic layer 212 is formed on the anode 211. The cathode 213 is formed of a transparent conductive film or the like on the organic layer 212 commonly across all of the pixels, that is, the entire surface of the display panel 70.

In the organic EL element 21, the organic layer 212 is formed by sequentially depositing a hole transport layer/hole injection layer, a luminescent layer, an electron transport layer, and an electron injection layer (not all shown) on the anode 211. In addition, as an electric current flows from the drive transistor 22 to the organic layer 212 through the anode 211 under electric-current driving using the drive transistor 22 of FIG. 2, light is emitted when electrons and holes are recombined in the luminescent layer within the organic layer 212.

The drive transistor 22 includes a gate electrode 221 made of molybdenum (Mo) or the like, source/drain areas 223 and 224 provided in both sides of the semiconductor layer 222, and a channel formation area 225 facing the gate electrode 221 of the semiconductor layer 222. The source/drain area 223 is electrically connected to the anode 211 of the organic EL element 21 through a contact hole.

A metal wiring line 75 made of aluminum (Al) or the like is formed on the insulation film 72. In this manner, the organic EL element 21 is formed on the glass substrate 711 in the unit of pixel using the insulation film 72, the insulation flattening film 73, and the wind insulation film 74. In addition, the organic EL element 21 is encapsulated by the encapsulation substrate (glass substrate) 77 using a passivation film 76. Through the aforementioned process, a display panel 70 is formed.

Meanwhile, the drive circuit section including the write scanning circuit 40, the power supply scanning circuit 50, or the like is formed in the circumferential portion of the display panel 70, that is, the bezel area of the display panel 70. Here, description will be made for the write scanning circuit 40 as the drive circuit section by way of example. The write scanning circuit 40 is configured using the inverter circuit made from the single-channel transistor in order to achieve a lowering of costs as described above. In addition, the single-channel transistor inverter circuit includes a capacitive element.

As described above, the capacitive element necessitates a relatively large layout area compared to circuit elements such as a transistor. Particularly, a significant layout area is necessary to form a large capacity capacitive element. For this reason, in order to mount the pixel array section 30 and the drive circuit section including the write scanning circuit 40 in the same substrate, an area dedicated to the capacitive element is prepared, and the capacitive element is formed thereon, separately from the circuit part including the transistor or the like of the drive circuit section.

Specifically, as shown in FIG. 11, a metal wiring line 78 made of molybdenum (Mo) or the like facing an existing metal wiring line 75 made of aluminum (Al) or the like is formed on the glass substrate 71 in an island shape so that a capacitive element C is formed by using the insulation film 72 between both wiring lines 75 and 78 as a dielectric member. Here, the capacitance value of the capacitive element C is determined based on an facing area between the metal wiring lines 75 and 78, a distance between the metal wiring lines 75 and 78, and a dielectric constant of the insulation film 72 as a dielectric member.

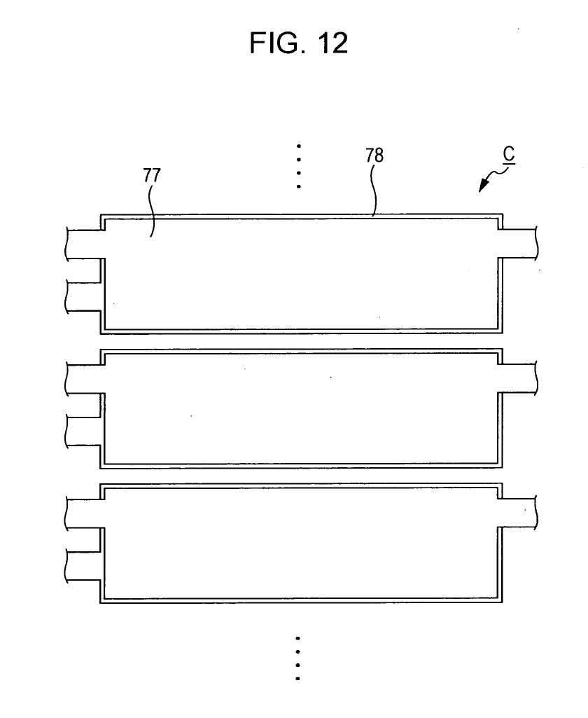

In this manner, a plurality of the capacitive elements C formed by using the insulation film 72 between the metal wiring lines 75 and 78 as a dielectric member are formed in the area dedicatedly prepared for the capacitive element in the bezel area of the display panel 70, for example, to match with the pixel row as shown in FIG. 12. Therefore, since a layout area occupied by the capacitive element within the drive circuit section increases when the drive circuit section including the write scanning circuit 40 is mounted in the bezel area of the display panel 70, the bezel area of the display panel 70 is enlarged. While only the area for forming the capacitive element C in the bezel area of the display panel 70 is illustrated in FIG. 11, the area for forming the capacitive element C (layout area) is necessary in addition to the area for forming other circuit parts.

### 2. Description of Embodiments

According to an embodiment of the present disclosure, when the drive circuit section having a circuit configuration including the capacitive element is mounted in the display panel 70 having the pixel array section 30, an organic layer is formed also in the circumferential portion of the pixel array section 30 on the display panel 70 through the same process as that of the organic layer 212 of the organic EL element 21. In addition, the capacitive element of the drive circuit section is formed by using the organic layer as a dielectric member.

Here, even when the organic layer used as a dielectric member of the capacitive element is formed in the circumferential portion of the pixel array section 30, the number of manufacturing processes does not increase because this organic layer is formed through the same process as that of the organic layer 212 of the organic EL element 21. In addition, since the organic layer formed in the circumferential portion of the pixel array section 30 is used as a dielectric member of the capacitive element, the area where the capacitive element has been formed can be used freely in the referential example described above, and can be used as an area for forming other circuit parts.

As a result, since the area used to form other circuit parts is not necessary in the referential example, a layout area occupied by the drive circuit section, and further, the circumferential portion of the pixel array section 30, that is the bezel area of the display panel 70 can be reduced by the unnecessary area. That is, when the drive circuit section having a circuit configuration including the capacitive element is mounted in the display panel 70, it is possible to obtain a narrow bezel of the display panel 70.

Hereinafter, embodiments of the present disclosure will be described in detail with reference to the accompanying drawings.

2-1. Mounting Structure of Display Panel in Embodiments of Present Disclosure

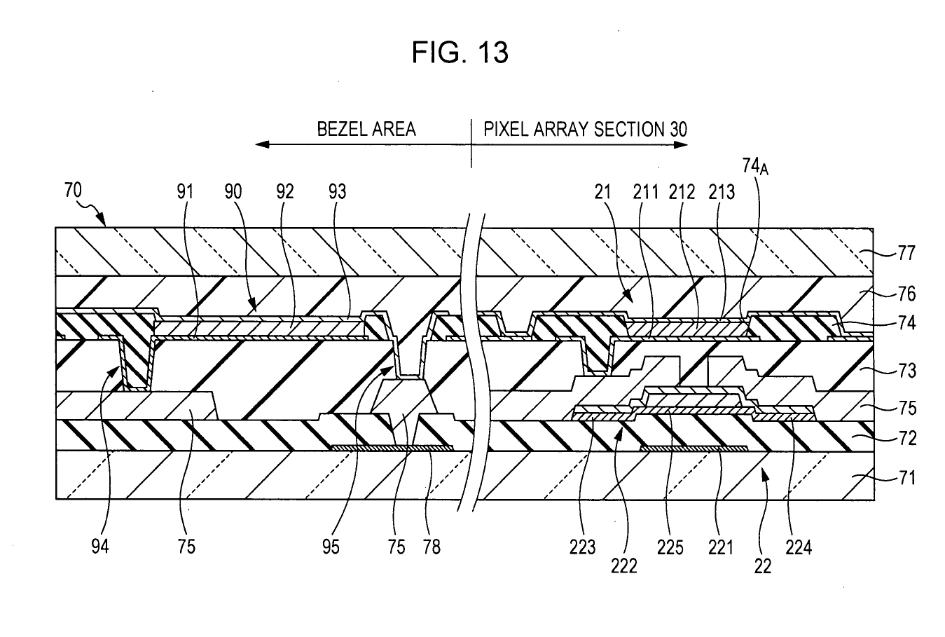

FIG. 13 is a cross-sectional diagram illustrating an mounting structure of the display panel according to an embodiment of the present disclosure. Like reference numerals denote like elements as in FIG. 11.

Referring to FIG. 13, the pixel array section 30 has the same configuration as that of the display panel of the reference example described above (refer to FIG. 11). That is, the circuit part (drive circuit part) including the drive transistor 22 or the like is formed on the glass substrate 71, and the organic EL element 21 is formed over that circuit part. Specifically, the insulation film 72, the insulation flattening film 73, and the wind insulation film 74 are sequentially formed on the glass substrate 71, and the organic EL element 21 is formed in the concave portion 74_{A} of the wind insulation film 74.

The organic EL element 21 includes an anode 211, an organic layer 212, and a cathode 213. The anode 211 is formed of metal or the like on the bottom of the concave portion 74_{A} of the wind insulation film 74. The organic layer 212 is formed on the anode 211. The cathode 213 is formed of a transparent conductive film or the like on the organic layer 212 commonly across all of the pixels, that is, the entire surface of the display panel 70.

The drive transistor 22 includes a gate electrode 221 made of molybdenum (Mo) or the like, source/drain areas 223 and 224 provided in both sides of the semiconductor layer 222, and a channel formation area 225 facing the gate electrode 221 of the semiconductor layer 222. The source/drain area 223 is electrically connected to the anode 205 of the organic EL element 21 through a contact hole.

A metal wiring line 75 made of aluminum (Al) or the like is formed on the insulation film 72. In this manner, the organic EL element 21 is formed on the glass substrate 711 in the unit of pixel using the insulation film 72, the insulation flattening film 73, and the wind insulation film 74. In addition, the organic EL element 21 is encapsulated by the encapsulation substrate (glass substrate) 77 using the passivation film 76 so that the display panel 70 is formed through the aforementioned processes.

Meanwhile, the capacitive element 90 is formed in the same layer as that of the organic EL element 21 in the area of the circumferential portion of the pixel array section 30, that is, the bezel area of the display panel 70. The capacitive element 90 has a device structure in which the organic layer 92 formed in the same layer and through the same process as that of the organic layer 212 of organic EL element 21 is interposed between both electrodes 91 and 93 to be used as a dielectric member. Similarly to the organic layer 212 of the organic EL element 21, the organic layer 92 of the capacitive element 90 can be obtained by forming a concave portion (corresponding to the concave portion 74_{A}) the wind insulation film 74 and forming the organic layer 92 within the concave portion.

Both electrodes 91 and 93 of the capacitive element 90 are formed of the same wiring line material and through the same process as those of the anode 211 and the cathode 213 of the organic EL element 21. In addition, the organic layer 92 is formed through the same process as that of the organic layer 212 of the organic EL element 21 as the organic layer 92 is also formed by depositing a hole transport layer on one electrode 91, similar to the organic layer 212.

One electrode 91 (corresponding to the anode 211) of the capacitive element 90 is electrically connected to the metal wiring line 75 through a contact section 94. The other electrode 93 (corresponding to the cathode 213) of the capacitive element 90 is electrically connected to the metal wiring line 78 through the contact section 95 and the metal wiring line 75. The metal wiring lines 75 and 78 are electrically connected to other circuit parts of the drive circuit section such as the write scanning circuit 40.

The capacitance value of the capacitive element 90 is determined by a facing area of both electrodes 91 and 93, a distance between both electrodes 91 and 93, and a dielectric constant of the organic layer 92 used as the dielectric member. Here, since the organic layer 92 is formed through the same process as that of the organic layer 212 of the organic EL element 21, the distance between both electrodes 91 and 93 is fixedly determined depending on the organic EL element 21. In addition, the dielectric constant of the organic layer 92 is fixedly determined depending on the emitted light color because a material of the luminescent layer is different depending on the emitted light color. Therefore, the capacitance value of the capacitive element 90 can be arbitrarily set by the facing area between both electrodes 91 and 93.

Furthermore, since the capacitive element 90 is not related to the emitted light color, it can be configured using only the organic layer emitting any single kind of light color considering a unit capacitance. That is, since a dielectric constant of the organic layer 92 is different depending on a material of the luminescent layer and the emitted light color as described above, the unit capacitance can be collectively set for all of the formed capacitive elements 90 by configuring the organic layer 92 of the capacitive element 90 using an organic layer emitting a single kind of light color.

The capacitive element 90 is formed in a dedicated area independent of the area for forming other circuit parts. Therefore, it is possible to obtain a large area as the area for forming the capacitive element 90. As a result, since it is possible to set a large facing area between both electrodes 91 and 93 of the capacitive element 90, a higher capacitance value can be set for the capacitance element 90 in comparison with a case where the capacitive element 90 is formed in the same area as that of other circuit parts. The capacitive element 90 necessitating a relatively high capacitance value includes, for example, capacitive elements C₁ to C₅ or the like in the inverter circuit 80 as described above.

A plurality of capacitive elements 90 are formed in the bezel area of the display panel 70 to match with pixel rows as shown in FIG. 12. Meanwhile, the underlying layer of the capacitive element 90, that is, the same layer as that of the circuit part of the pixel 20 can be freely used except for the contact sections 94 and 95. Therefore, although not shown in FIG. 13, the underlying layer of the capacitive element 90 can be used as a part or the entirety of the circuit parts other than the capacitive element 90 included in the drive circuit section, specifically, the circuit parts including the single-channel transistor. The circuit parts other than the capacitive element 90 may be formed through the same process as that of the circuit part formed to face the light-emission surface of the organic EL element 21.

As described above, the drive circuit section having a circuit configuration including the capacitive element 90 is mounted in the display panel 70, the organic layer 92 is formed also in the bezel area of the display panel 70, and the capacitive element 90 is formed by using the organic layer 90 as a dielectric member. As a result, the following advantages and effects can be obtained.

That is, even when the organic layer 92 of the capacitive element 90 used as a dielectric member is formed, the number of manufacturing processes does not increase as the organic layer 92 is formed through the same process as that of the organic layer 212 of the organic EL element 21. In addition, since the organic layer 92 formed in the bezel area of the display panel 70 is used as a dielectric member of the capacitive element 90, the area of the underlying layer of the organic layer 92 can be used for the area for forming other circuit parts.

As a result, since it is not necessary to separately obtain the area for forming other circuit parts, it is possible to reduce the layout area occupied by the drive circuit section and further the circumferential portion of the pixel array section 30 (that is, the bezel of the display panel 70) in that extent. That is, if the drive circuit section having a circuit configuration including the capacitive element 90 is mounted in the display panel 70, it is possible to reduce the bezel area of the display panel 70, that is, obtain a narrow frame.

2-2. Method of Manufacturing Display Panel in Embodiments

In order to manufacture the display panel 70 having the aforementioned configuration, in the process of forming the circuit part including the drive transistor 22 of the pixel 20 on the glass substrate 71, other circuit parts of the drive circuit section such as the write scanning circuit 40 are also formed in the bezel area of the display panel 70 as shown in FIG. 13. It is noted that other circuit parts are omitted in FIG. 13 for simplicity. In addition, one electrode 91, the organic layer 92, and the other electrode 93 are also formed in the bezel area of the display panel 70 through the same process as the process of forming the organic EL element 21 so that the capacitive element 90 is formed by using the organic layer 92 as a dielectric member.

According to such a method of manufacturing the display panel 70, that is, the method of manufacturing the organic EL display device, it is possible to form the capacitive element 90 in the process of forming the organic EL element 21 without increasing the number of manufacturing processes. Therefore, it is possible to manufacture the display panel 70 with the drive circuit section including the capacitive element 90 obtained by using the organic layer 92 as a dielectric member while the manufacturing costs are suppressed.

### 3. Modifications

While the aforementioned embodiments have been described by exemplifying a case where the drive circuit of the organic EL element 21 has a pixel configuration basically including two transistors, that is, the drive transistor 22 and the write transistor 23, the scope of the present disclosure is not limited by such a pixel configuration. For example, embodiments of the present disclosure may be applied to various pixel configurations such as a pixel configuration in which the electric potential of the power supply line 32 is fixed, and a light-emission control transistor is connected in series to the drive transistor 22 so that light emission/non-emission of the organic EL element 21 is controlled by the light-emission control transistor.

For example, in the case of an organic EL display device having a pixel configuration including the light-emission control transistor, a scanning circuit is separately necessary for controlling the light-emission control transistor as a drive circuit section. In such a case of an organic EL display device, it is possible to also apply embodiments of the present disclosure to the scanning circuit for controlling the light-emission control transistor.

### 4. Applications

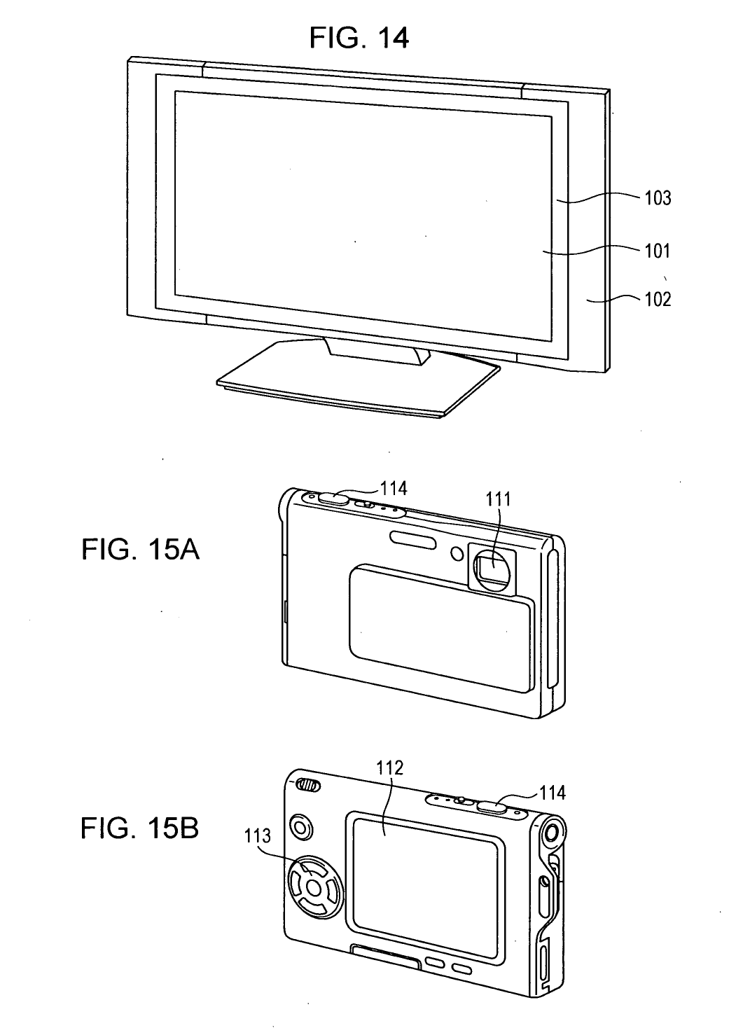

The organic EL display device according to the aforementioned embodiment of the present disclosure may be applied to a display section (display device) of an electronic apparatus for displaying image signals input to or created within the electric apparatus as images or videos in a wide variety of fields. For example, embodiments of the present disclosure may be applied to various electronic apparatuses such as a digital camera, a laptop computer, a mobile terminal such as a mobile phone, and a video camera, as shown in FIGS. 14 to 18.

In this manner, by using the organic EL display device according to an embodiment of the present disclosure as a display section of the electronic apparatus in a variety of fields, it is possible to reduce the size of the device mainframe in various electronic apparatuses. That is, as apparent from description of the aforementioned embodiments, it is possible to obtain a narrow bezel of the display panel in the organic EL display device according to an embodiment of the present disclosure if the drive circuit section having a circuit configuration including the capacitive element is mounted in the display panel. Therefore, since it is possible to reduce the size of the bezel of the display section in various electronic apparatuses, it is possible to achieve miniaturization of a device mainframe.

The organic EL display device according to an embodiment of the present disclosure includes an encapsulated module configuration. For example, embodiments of the present disclosure may be applied to a display module obtained by attaching a face unit such as transparent glass to the pixel array section 30. Such a transparent face unit may include a color filter, a protection film, a light-shield film, or the like. Furthermore, the display module may include a circuit section for inputting/outputting signals or the like to/from the pixel array section, a flexible print circuit (FPC), and the like.

Electronic Apparatus

Hereinafter, examples of the electronic apparatus according to an embodiment of the present disclosure will be described in detail.

FIG. 14 is a perspective view illustrating an exterior of a television set according to the principles of the present disclosure. The television set according to the present example includes an image display screen unit 101 having a front panel 102, a filter glass 103, or the like, and is manufactured using the organic EL display device according to the principle of the present disclosure as such an image display screen unit 101.

FIGS. 15A and 15B are perspective views illustrating an exterior of a digital camera according to the principle of the present disclosure, in which FIG. 15A is a front perspective view, and FIG. 15B is a rear perspective view. The digital camera according to the present example includes a flash light emission unit 111, a display unit 112, a menu switch 113, a shutter button 114, and the like, and is manufactured using the organic EL display device according to an embodiment of the present disclosure as such a display unit 112.

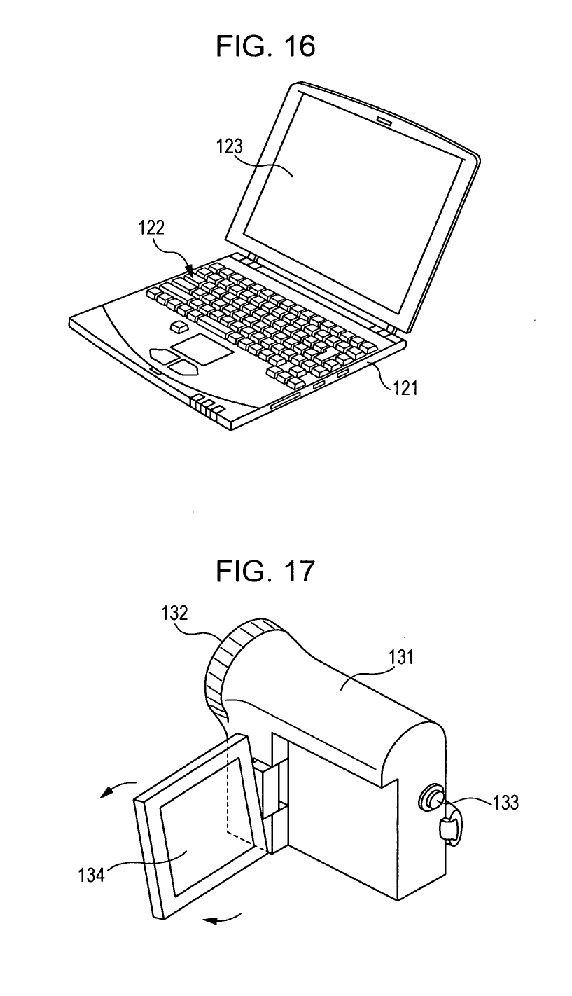

FIG. 16 is a perspective view illustrating an exterior of a laptop computer according to an embodiment of the present disclosure. The laptop computer according to the present example includes a keyboard 122 manipulated to enter characters in the mainframe 121, a display unit 123 for display images, and the like, and is manufactured using the organic EL display device according to an embodiment of the present disclosure as such a display unit 134.

FIG. 17 is a perspective view illustrating an exterior of a video camera according to an embodiment of the present disclosure. The video camera according to an embodiment of the present disclosure includes a mainframe unit 131, a subject capturing lens 132 provided in the side face looking the front, a start/stop switch 133 used in the image capturing, a display unit 134, and the like, and is manufactured using the organic EL display device according to an embodiment of the present disclosure as such a display unit 123.

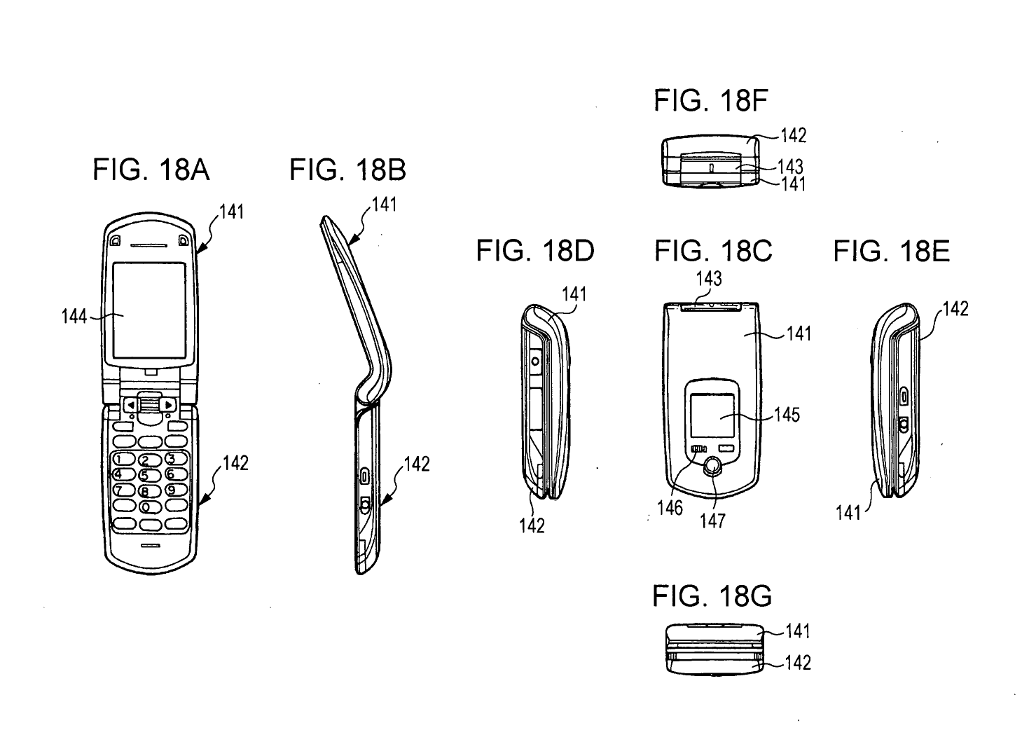

FIGS. 18A to 18G are exterior views illustrating a mobile terminal, for example, a mobile phone according to an embodiment of the present disclosure, in which FIG. 18A is a front view in an open state, in which FIG. 18B is a side view thereof, FIG. 18C is a front view in a closed state, FIG. 18D is a left-side view, FIG. 18E is a right-side view, FIG. 18F is a top view, and FIG. 18G is a bottom view. The mobile phone according to an embodiment of the present disclosure includes an upper casing 141, a lower casing 142, a connector (here, a hinge unit) 143, a display 144, a sub-display 145, a picture light 146, a camera 147, and the like, and is manufactured using the organic EL display device according to an embodiment of the present disclosure as the display 144 or the sub-display 145.

The present disclosure contains subject matter related to that disclosed in Japanese Priority Patent Application JP 2010-160407 filed in the Japan Patent Office on Jul. 15, 2010, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An organic electroluminescent (EL) display device comprising:
a pixel array section in which pixels having organic EL elements are arranged; and
a drive circuit section provided in a circumferential portion of the pixel array section on the same substrate as that of the pixel array section, the drive circuit section having a circuit configuration including a capacitive element,
wherein the capacitive element uses, as a dielectric member, an organic layer formed in the circumferential portion of the pixel array section through the same process as that of the organic layer of the organic EL element.

2. The organic EL display device according to claim 1, wherein the drive circuit section is a scanning circuit for sequentially selecting each pixel of the pixel array section,
the scanning circuit has an inverter circuit obtained by combining a single-channel transistor with a capacitive element, and
the capacitive element of the inverter circuit uses, as a dielectric member, the organic layer formed in the circumferential portion of the pixel array section.

3. The organic EL display device according to claim 2, wherein the scanning circuit has a circuit part including a single-channel transistor under the organic layer used as a dielectric member of the capacitive element of the inverter circuit.

4. The organic EL display device according to claim 2, wherein the inverter circuit includes
a first transistor receiving, as a gate input, a voltage corresponding to an input voltage input through an input terminal,
a second transistor that is connected in series to the first transistor and has a gate electrode connected to the input terminal,
a first capacitive element connected between a gate and a source of the first transistor, and
a second capacitive element connected between a common node between the first and second transistors and the input terminal,
wherein the second capacitive element uses an organic layer formed in a circumferential portion of the pixel array section as a dielectric member.

5. The organic EL display device according to claim 4, wherein a capacitance value of the second capacitive element is higher than that of the first capacitive element.

6. The organic EL display device according to claim 5, wherein the pixel has a mobility correction capability for correcting the mobility of the drive transistor by applying a negative feedback to a gate-source voltage of the drive transistor with a correction amount corresponding to an electric current flowing through a drive transistor for driving the organic EL element, and
the scanning circuit creates a write scanning signal for determining a correction time for correcting the mobility using an output pulse of the inverter circuit as a reference, and determines a transition timing of the output pulse based on a capacitive coupling by the second capacitive element.

7. The organic EL display device according to claim 2, wherein the organic layer of the capacitive element is made from an organic layer emitting a single type of light color.

8. A display device comprising:
a pixel array section in which pixels including organic EL elements are arranged; and
a drive circuit section provided in a circumferential portion of the pixel array section, the drive circuit section including a capacitive element,
wherein the capacitive element uses the same organic layer as that of the organic EL element as a dielectric member.

9. The display device according to claim 8, wherein the drive circuit section has an inverter circuit obtained by combining a transistor with the capacitive element.

10. The display device according to claim 9, wherein the inverter circuit has the transistor provided under the organic layer of the capacitive element.

11. A method of manufacturing an organic EL display device including a pixel array section in which pixels having organic EL elements are arranged, and a drive circuit section provided in a circumferential portion of the pixel array section on the same substrate as that of the pixel array section, the drive circuit section having a circuit configuration including a capacitive element, the method comprising:
forming an organic layer in a circumferential portion of the pixel array section through the same process as that of an organic layer of the organic EL element; and
forming the capacitive element by using an organic layer in a circumferential portion of the pixel array section as a dielectric member.

12. An electronic apparatus comprising an organic EL display device, the organic EL display device including:
a pixel array section in which pixels having organic EL elements are arranged; and
a drive circuit section provided in a circumferential portion of the pixel array section on the same substrate as that of the pixel array section, the drive circuit section having a circuit configuration including a capacitive element,
wherein the capacitive element uses an organic layer formed in a circumferential portion of the pixel array section through the same process as that of the organic layer of the organic EL element as a dielectric member.
